(19) United States
(12) Patent Application Publication
(10) Pub. No.: US 2026/0313996 A1
(43) Pub. Date: Oct. 8, 2026

(54) NITRIDE SEMICONDUCTOR DEVICE AND MANUFACTURING METHOD OF NITRIDE SEMICONDUCTOR DEVICE

(71) Applicant: WAVETEK MICROELECTRONICS CORPORATION, Hsinchu County (TW)

(72) Inventors: Geng-Yen LEE, Hsinchu County (TW); Yan-Ting CHUANG, Hsinchu County (TW); Chun-Liang HOU, Hsinchu County (TW)

(21) Appl. No.: 19/347,732

(22) Filed: Oct. 2, 2025

(30) Foreign Application Priority Data
Apr. 2, 2025 (TW) 114112873

(51) Int. Cl. H10D 62/824; H01L 23/528; H10D 30/01; H10D 30/47; H10D 62/10; H10D 64/00; H10D 64/27

(52) U.S. Cl. CPC H10D 62/824; H10D 30/015; H10D 30/471; H10D 62/102; H10D 64/111; H10D 64/514; H10D 64/518; H10W 20/435

(57) ABSTRACT

A nitride semiconductor device includes a substrate, a channel layer, a first polarization layer, a polarization control layer and a second polarization layer. The channel layer is disposed on the substrate, the first polarization layer is disposed on the channel layer, the polarization control layer is disposed on the first polarization layer and the second polarization layer is disposed on the polarization control layer. The lattice constant of the first polarization layer and the lattice constant of the second polarization layer are less than the lattice constant of the polarization control layer. By the configurations of the first polarization layer, the polarization control layer and the second polarization layer, the 2DEG of the channel layer is adjusted.

### CROSS-REFERENCE TO RELATED APPLICATIONS

This application claims the priority benefit of Taiwan Patent Application Serial Number 114112873, filed on Apr. 2, 2025, the full disclosure of which is incorporated herein by reference.

### TECHNICAL FIELD OF THE INVENTION

The present disclosure is related to the technical field of semiconductors and particularly relates to a nitride semiconductor device and a manufacturing method of a nitride semiconductor device.

### DESCRIPTION OF THE PRIOR ART

The technology of GaN High electron mobility transistor (GaN HEMT) starts the new generation of a power converter and realizes an unprecedentedly high operation frequency and unprecedentedly high power density. The power converter utilizing the GaN HEMT would have greater parasitic parameters inevitably and result in gate voltage oscillations during high-speed switching, and the threshold voltage of the GaN HEMT is lower, thereby contributing to the false turn-on of the GaN HEMT.

For the normally-off operation of the GaN HEMT, the common practices are as follows: (1) a p-type GaN layer is disposed under the gate electrode of the GaN HEMT to increase the threshold voltage of the GaN HEMT. Because the p-type GaN layer usually needs to be matched with the gate electrode, the p-type GaN layer requires etching; the etching of the p-type GaN layer would damage the surface of the barrier layer of the GaN HEMT, thereby affecting the performance of the GaN HEMT. (2) Fluoride ion treatment is performed in the surroundings of the gate electrode of the GaN HEMT to accumulate fluoride ions at the boundary between a channel layer and the barrier layer, thus increasing the threshold voltage of the GaN HEMT. The fluoride ions would damage the surface of the barrier layer of the GaN HEMT, thereby affecting the performance of the GaN HEMT.

### SUMMARY

In light of the aforementioned descriptions, the present disclosure provides a nitride semiconductor device and a manufacturing method of a nitride semiconductor device to solve the problem of the false turn-on of the GaN HEMT.

Based on the aforementioned descriptions, the present disclosure provides a nitride semiconductor device. The nitride semiconductor device includes a substrate, a channel layer, a first polarization layer, a polarization control layer and a second polarization layer. The channel layer is disposed on the substrate, the first polarization layer is disposed on the channel layer, the polarization control layer is disposed on the first polarization layer, and the second polarization layer is disposed on the polarization control layer. The lattice constant of the first polarization layer and the lattice constant of the second polarization layer are less than the lattice constant of the polarization control layer.

Based on the aforementioned descriptions, the present disclosure provides a nitride semiconductor device. The nitride semiconductor device includes the substrate, the channel layer, a spacer layer and a polarization layer. The channel layer is disposed on the substrate, the spacer layer is disposed on the channel layer, and the polarization layer is disposed on the spacer layer.

Based on the aforementioned descriptions, the present disclosure provides a manufacturing method of a nitride semiconductor device. The manufacturing method of the nitride semiconductor device includes: sequentially forming the channel layer, a first spacer layer, the first polarization layer, the polarization control layer, a second spacer layer, the second polarization layer and a surface cap layer on the substrate; partially etching the channel layer, the first spacer layer, the first polarization layer, the polarization control layer, the second spacer layer, the second polarization layer and the surface cap layer to form a mesa structure, wherein the mesa structure exposes the channel layer; forming a first passivation layer on the mesa structure, and forming a drain electrode and a source electrode on two sides of the mesa structure, wherein the drain electrode and the source electrode are located on the first passivation layer and extends from the first passivation layer to the channel layer; forming a second passivation layer on the first passivation layer, and partially etching the second passivation layer so that the etched second passivation layer has a through hole, wherein the through hole extends to the second spacer layer; forming a gate insulator layer on the second passivation layer and in the through hole; forming a gate electrode on the gate insulator layer.

Based on the aforementioned descriptions, the present disclosure provides a manufacturing method of a nitride semiconductor device. The manufacturing method of the nitride semiconductor device includes: sequentially forming the channel layer, the spacer layer and the polarization layer on the substrate; partially etching the channel layer, the spacer layer and the polarization layer to form a mesa structure, wherein the mesa structure exposes the channel layer; forming a first passivation layer on the mesa structure, and forming a drain electrode and a source electrode on two sides of the mesa structure, wherein the drain electrode and the source electrode are located on the first passivation layer and extends from the first passivation layer to the channel layer; forming a second passivation layer on the first passivation layer, and partially etching the second passivation layer so that the etched second passivation layer has a through hole, wherein the through hole extends to the spacer layer; forming a gate insulator layer on the second passivation layer and in the through hole; forming a gate electrode on the gate insulator layer.

In view of the above descriptions, the nitride semiconductor device and the manufacturing method of the nitride semiconductor device adjusts the 2DEG of the channel layer by forming the first polarization layer, the polarization control layer and the second polarization layer to achieve the normally-off operation of the GaN HEMT.

The aforementioned description of the present disclosure is merely the outline of the technical solutions of the present disclosure. In order to understand the technical solutions of the present disclosure clearly and to implement the present disclosure according to the content of the specification, the better embodiments of the present disclosure given herein below with accompanying drawings are used to describe the present disclosure in detail.

### BRIEF DESCRIPTION OF DRAWINGS

FIG. 1 depicts the cross section diagram of a nitride semiconductor device according to one embodiment of the present disclosure.

FIG. 2 depicts the schematic diagram of the spontaneous polarization and the piezoelectric polarization of a channel layer, a first polarization layer and a polarization control layer according to one embodiment of the present disclosure.

FIG. 3 depicts the cross section diagram of a nitride semiconductor device according to another embodiment of the present disclosure.

FIG. 4 depicts the cross section diagram of a nitride semiconductor device according to yet embodiment of the present disclosure.

FIG. 5 depicts the cross section diagram of a nitride semiconductor device according to still embodiment of the present disclosure.

FIG. 6 depicts the cross section diagram of a nitride semiconductor device according to yet another embodiment of the present disclosure.

FIG. 7 depicts the cross section diagram of a nitride semiconductor device according to still another embodiment of the present disclosure.

FIG. 8 depicts the cross section diagram of a nitride semiconductor device according to still yet another embodiment of the present disclosure.

FIG. 9 depicts the flowchart of a manufacturing method of a nitride semiconductor device according to one embodiment of the present disclosure.

FIG. 10A to FIG. 10F depict the cross section diagram of the manufacturing method of the nitride semiconductor device at different stages according to one embodiment of the present disclosure.

FIG. 11 depicts the flowchart of a manufacturing method of a nitride semiconductor device according to another embodiment of the present disclosure.

FIG. 12A and FIG. 12B depict the cross section diagram of forming the ILD layer and the metal plugs in the manufacturing method of the nitride semiconductor device according to another embodiment of the present disclosure.

FIG. 13 depicts the flowchart of a manufacturing method of a nitride semiconductor device according to yet embodiment of the present disclosure.

FIG. 14 depicts the cross section diagram of forming the oxide layer in the manufacturing method of the nitride semiconductor device according to yet another embodiment of the present disclosure.

FIG. 15 depicts the flowchart of a manufacturing method of a nitride semiconductor device according to still embodiment of the present disclosure.

FIG. 16A to FIG. 16F depict the cross section diagram of the manufacturing method of the nitride semiconductor device at different stages according to still embodiment of the present disclosure.

FIG. 17 depicts the flowchart of a manufacturing method of a nitride semiconductor device according to yet another embodiment of the present disclosure.

### DETAILED DESCRIPTION

The specific embodiments of the present disclosure given herein below is used to explain the implementation of the present disclosure. A person skilled in the art easily understands the advantages and the effects of the present disclosure from the content of the present disclosure.

It should be noted that the embodiments and the features in the embodiments of the present disclosure can be combined with each other without conflict. The present disclosure will be described in detail below with reference to accompanying drawings and in conjunction with the embodiments. In order to provide those in the art with better understanding of the solution of the disclosure, the technical solutions in the embodiments of the present disclosure will be described clearly and completely below in conjunction with the accompanying drawings in the embodiments of the present disclosure. Apparently, the described embodiments are merely a part of the embodiments of the present disclosure and not all embodiments of the present disclosure. Based on the embodiments of the present disclosure, all other embodiments obtained by a person skilled in the art shall fall within the scope of protection of the present disclosure.

It should be noted that the terms “first”, “second”, etc. in the specification and claims of the present disclosure and in the aforementioned accompanying drawings are used to distinguish similar objects and need not be used to describe a particular order or sequence. Furthermore, the terms “comprising” and “having”, and any variation thereof, are intended to encompass a non-exclusive inclusion, for example, a series of steps or units comprising processes, methods, systems, products or equipment need not be limited to those steps or units clearly listed but may include other steps or units not clearly listed or inherent to those processes, methods, products or equipment.

Please refer to FIG. 1, which depicts the cross section diagram of a nitride semiconductor device according to one embodiment of the present disclosure. As shown in FIG. 1, a nitride semiconductor device 1A includes a substrate 10A, a channel layer 20A, a first polarization layer 30A, a polarization control layer 40A and a second polarization layer 50A. The channel layer 20A is disposed on the substrate 10A, the first polarization layer 30A is disposed on the channel layer 20A, the polarization control layer 40A is disposed on the first polarization layer 30A, and the second polarization layer 50A is disposed on the polarization control layer 40A. In brief, the channel layer 20A, the first polarization layer 30A, the polarization control layer 40A and the second polarization layer 50A are sequentially disposed on the substrate 10A. The lattice constant of the first polarization layer 30A and the lattice constant of the second polarization layer 50A are less than the lattice constant of the polarization control layer 40A.

The substrate 10A may be a Si (111) substrate, a GaN substrate, an AlN substrate, a sapphire substrate, a SiC substrate or a diamond substrate. Because the crystal structure of a nitride is usually a wurtzite structure, the substrate of which the crystal structure is a hexagonal crystal system is selected as the substrate 10A of the nitride semiconductor device 1A. Undoubtedly, the substrate 10A of the nitride semiconductor device 1A may be the other type substrate which has an ability to carry nitride films and is not limited to the substrate of which the crystal structure is the hexagonal crystal system.

The channel layer 20A is located between the substrate 10A and the first polarization layer 30A. The boundary between the channel layer 20A and the first polarization layer 30A is the position where two-dimensional electron gas (2DEG) forms. In addition, a nucleation layer may be selectively disposed between the channel layer 20A and the substrate 10A to facilitate the formation of subsequent semiconductor layers.

The first polarization layer 30A is located between the channel layer 20A and the polarization control layer 40A. The lattice constant of the first polarization layer 30A is less than the lattice constant of the channel layer 20A, the bandgap of the first polarization layer 30A is greater than the bandgap of the channel layer 20A, and the junction of the first polarization layer 30A and the channel layer 20A is a heterojunction. Because the bandgap of the first polarization layer 30A is different from the bandgap of the channel layer 20A, the energy band at the boundary between the channel layer 20A and the first polarization layer 30A bends, and thus, a triangular quantum well structure is formed. The triangular quantum well structure results in generating the 2DEG at the boundary between the channel layer 20A and the first polarization layer 30A.

The polarization control layer 40A is located between the first polarization layer 30A and the second polarization layer 50A. The bandgap of the polarization control layer 40A is less than the bandgap of the first polarization layer 30A, and the lattice constant of the polarization control layer 40A is greater than the lattice constant of the first polarization layer 30A.

The bandgap of the second polarization layer 50A is greater than the bandgap of the polarization control layer 40A and may be the same as or different from the bandgap of the first polarization layer 30A; the lattice constant of the second polarization layer 50A is less than the lattice constant of the polarization control layer 40A and may be the same as or different from the lattice constant of the first polarization layer 30A. The polarization control layer 40A and the second polarization layer 50A collaboratively adjust the 2DEG at the boundary between the channel layer 20A and the first polarization layer 30A.

The materials of the channel layer 20A, the first polarization layer 30A, the polarization control layer 40A and the second polarization layer 50A may include GaN, AlGaN, InAlN, AlN, ScGaN, ScAlN, BN, AlInGaN or InGaN.

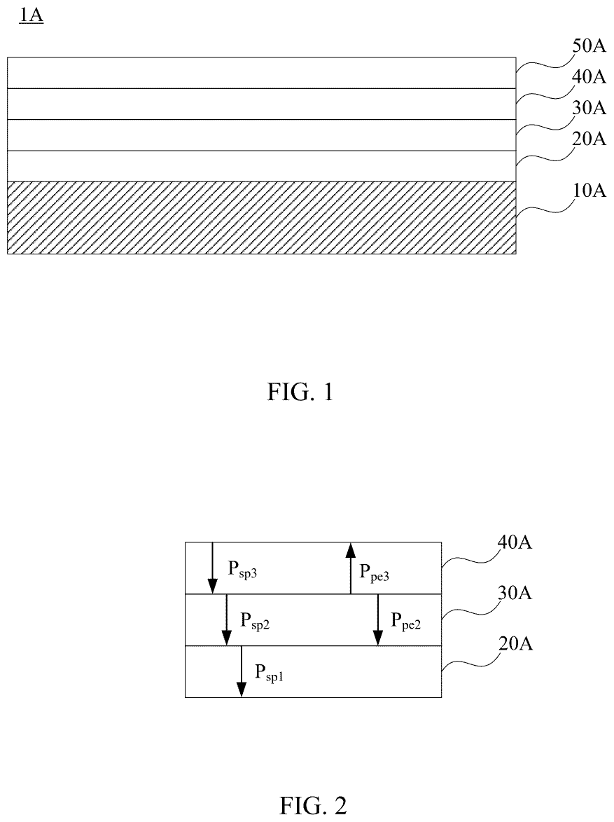

The operation mechanism of adjusting the 2DEG at the boundary between the channel layer 20A and the first polarization layer 30A by the polarization control layer 40A and the second polarization layer 50A will be explained as follows. Please further refer to FIG. 2, which depicts the schematic diagram of the spontaneous polarization and the piezoelectric polarization of the channel layer, the first polarization layer and the polarization control layer according to one embodiment of the present disclosure. As shown in FIG. 2, the first polarization layer 30A and the polarization control layer 40A are sequentially disposed on the channel layer 20A. For example, the material of the channel layer 20A is GaN; the material of the first polarization layer 30A is AlₓGa₁₋ₓN, x=0.08~1; the material of the polarization control layer 40A is Al_{y}Ga_{1-y}N, y=0~0.6, x>y. In other words, the Al composition ratio of the first polarization layer 30A is greater than the Al composition ratio of the polarization control layer 40A. In addition, the thickness of the channel layer 20A is greater than the thickness of the first polarization layer 30A and the thickness of the polarization control layer 40A, and the thickness of the polarization control layer 40A is greater than the thickness of the first polarization layer 30A.

Herein, the spontaneous polarization and the piezoelectric polarization affecting the 2DEG would be explained as follows. Because the crystal structure of a III-nitride is the wurtzite structure and belongs to a non-centrosymmetric crystal, and Ga atoms and N atoms are not symmetrically distributed, the center of a positive charge and the center of a negative charge are unable to overlap, thus causing the spontaneous polarization in a crystal direction (0001). Piezoelectric effect is a phenomenon where mechanical energy is converted into electrical energy in piezoelectric materials, and the piezoelectric polarization is that the piezoelectric materials generate the piezoelectric effect under stress to result in redistributing the charges on the interior of the crystal.

The spontaneous polarization coefficient of GaN is −0.029C/m². The spontaneous polarization coefficient of AlGaN is (−0.052x−0.029)C/m², x is the Al composition ratio of AlGaN, and the spontaneous polarization coefficient of GaN and the spontaneous polarization coefficient of AlGaN are all negative values; the piezoelectric polarization coefficient of AlGaN is

$$2 \frac{a - {a}_{0}}{a} ( {e}_{31} - {e}_{33} \frac{{C}_{13}}{{C}_{33}} ) ,$$

e₃₁ and e₃₃ are piezoelectric coefficients, C₁₃ and C₃₃ are moduli of elasticity, a₀ is the lattice constant of AlGaN without being subject to any stress, and a is the lattice constant of AlGaN after being subject to the stress. The value of

$$( {e}_{31} - {e}_{33} \frac{{C}_{13}}{{C}_{33}} )$$

is the negative value; after AlGaN is subject to tensile stress, the value of

$$2 \frac{a - {a}_{0}}{a}$$

is a positive value; after AlGaN is subject to compressive stress, the value of

$$2 \frac{a - {a}_{0}}{a}$$

is the negative value.

The spontaneous polarization coefficient of the channel layer 20A is denoted by Pₛₚ₁; the spontaneous polarization coefficient of the first polarization layer 30A is denoted by Pₛₚ₂, and the piezoelectric polarization coefficient of the first polarization layer 30A is denoted by Pₚₑ₂; the spontaneous polarization coefficient of the polarization control layer 40A is denoted by Pₛₚ₃, and the piezoelectric polarization coefficient of the polarization control layer 40A is denoted by Pₚₑ₃. Because the spontaneous polarization coefficients of GaN and AlGaN are all negative values, the spontaneous polarization direction of the channel layer 20A, the spontaneous polarization direction of the first polarization layer 30A and the spontaneous polarization direction of the polarization control layer 40A are all downward.

Because the lattice constant of the first polarization layer 30A is less than the lattice constant of the channel layer 20A, the first polarization layer 30A is subject to the tensile stress, the piezoelectric polarization coefficient Pₚₑ₂ of the first polarization layer 30A is the negative value, and the piezoelectric polarization direction of the first polarization layer 30A is downward. By the spontaneous polarization of the channel layer 20A and the spontaneous polarization and the piezoelectric polarization of the first polarization layer 30A, positive polarization charges accumulate at the boundary between the channel layer 20A and the first polarization layer 30A, and the accumulated positive polarization charges attract the 2DEG.

Because the lattice constant of the polarization control layer 40A is greater than the lattice constant of the first polarization layer 30A, the polarization control layer 40A is subject to the compressive stress, the piezoelectric polarization coefficient Pₚₑ₃ of the polarization control layer 40A is the positive value, and the piezoelectric polarization direction of the polarization control layer 40A is upward. By the spontaneous polarization and the piezoelectric polarization of the polarization control layer 40A and the spontaneous polarization of the first polarization layer 30A, negative polarization charges accumulate at the boundary between the polarization control layer 40A and the first polarization layer 30A, and the accumulated negative polarization charges attract the holes of the first polarization layer 30A to affect the positive polarization charges located at the boundary between the channel layer 20A and the first polarization layer 30A, thereby controlling the generation of the 2DEG at the boundary between the channel layer 20A and the first polarization layer 30A.

For example, the material of the second polarization layer 50A is Al_{z}Ga_{1-z}N, z=0.08~1, and z>y. The Al composition ratio of the second polarization layer 50A is greater than the Al composition ratio of the polarization control layer 40A and is different from the Al composition ratio of the first polarization layer 30A.

Because the lattice constant of the second polarization layer 50A is less than the lattice constant of the polarization control layer 40A, the second polarization layer 50A is subject to the tensile stress, the piezoelectric polarization coefficient of the second polarization layer 50A is the negative value, and the piezoelectric polarization direction of the second polarization layer 50A is downward. By the spontaneous polarization and the piezoelectric polarization of the second polarization layer 50A and the spontaneous polarization of the polarization control layer 40A, positive polarization charges accumulate at the boundary between the second polarization layer 50A and the polarization control layer 40A, and the accumulated positive polarization charges attract the 2DEG to affect the negative polarization charges located at the boundary between the first polarization layer 30A and the polarization control layer 40A, thereby controlling the generation of the 2DEG at the boundary between the channel layer 20A and the first polarization layer 30A.

In the nitride semiconductor device of the present embodiment, by the configurations of the polarization control layer and the second polarization layer, the positive polarization charges accumulating at the boundary between the channel layer 20A and the first polarization layer 30A are affected, thereby controlling the generation of the 2DEG.

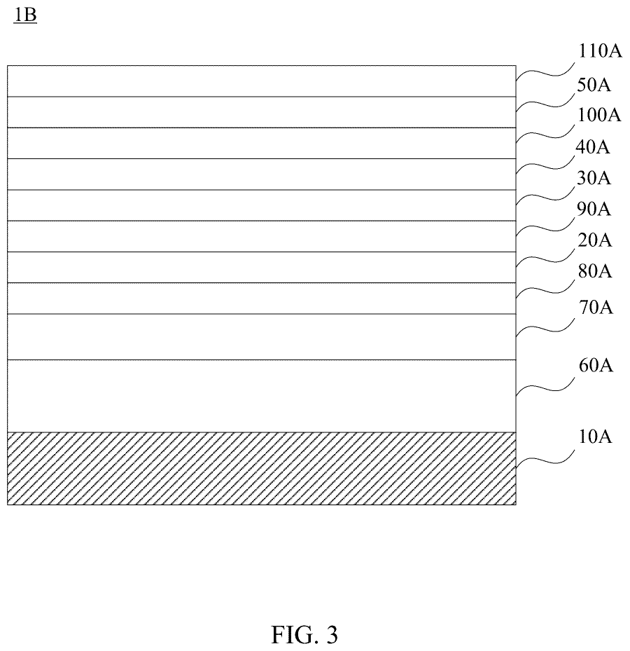

Please refer to FIG. 3, which depicts the cross section diagram of a nitride semiconductor device according to another embodiment of the present disclosure. As shown in FIG. 3, a nitride semiconductor device 1B includes the substrate 10A, the channel layer 20A, the first polarization layer 30A, the polarization control layer 40A, the second polarization layer 50A, a first buffer layer 60A, a second buffer layer 70A, a back barrier layer 80A, a first spacer layer 90A, a second spacer layer 100A and a surface cap layer 110A. The configuration of the nitride semiconductor device 1B shown in FIG. 3 is similar to the configuration of the nitride semiconductor device 1A shown in FIG. 1, and the similarities between the nitride semiconductor device 1B shown in FIG. 3 and the nitride semiconductor device 1A shown in FIG. 1 would not be repeated.

The first buffer layer 60A is disposed on the substrate 10A and is located between the substrate 10A and the channel layer 20A. The first buffer layer 60A provides a smoother crystal surface to facilitate the formation of the subsequent semiconductor layers and to relieve the lattice mismatch between the substrate 10A and the first buffer layer 60A. The first buffer layer 60A may be a AlN/GaN super lattice, a grading GaN buffer layer or an abrupt GaN buffer layer. The second buffer layer 70A is disposed on the first buffer layer 60A and is located between the first buffer layer 60A and the channel layer 20A. By the configuration of the second buffer layer 70A, the leakage current between the substrate 10A and the semiconductor layer above the second buffer layer 70A is reduced, and the breakdown voltage of the nitride semiconductor device is increased. The material of the second buffer layer 70A may be a C-doped GaN buffer layer or a Fe-doped GaN buffer layer.

The back barrier layer 80A is disposed on the second buffer layer 70A and is located between the second buffer layer 70A and the channel layer 20A. By the configuration of the back barrier layer 80A, the defects generating between the second buffer layer 70A and the channel layer 20A due to the lattice mismatch are improved, and the leakage current of the nitride semiconductor device is reduced. The material of the back barrier layer 80A may be AlN, AlGaN or InGaN.

In the present embodiment, the nitride semiconductor device has the first buffer layer 60A, the second buffer layer 70A and the back barrier layer 80A. In another embodiment, the nitride semiconductor device has the first buffer layer 60A and the back barrier layer 80A or the second buffer layer 70A and the back barrier layer 80A. In yet another embodiment, the nitride semiconductor device has the first buffer layer 60A, the second buffer layer 70A or the back barrier layer 80A.

The first spacer layer 90A is disposed between the first polarization layer 30A and the channel layer 20A to assist in inducing the 2DEG at the boundary between the channel layer 20A and the first polarization layer 30A. The first spacer layer 90A is a thin layer; the thickness of the first spacer layer 90A is less than the thickness of the first polarization layer 30A and the thickness of the channel layer 20A. The second spacer layer 100A is disposed between the polarization control layer 40A and the second polarization layer 50A to assist in inducing the 2DEG at the boundary between the polarization control layer 40A and the second polarization layer 50A. The second spacer layer 100A is the thin layer; the thickness of the second spacer layer 100A is less than the thickness of the polarization control layer 40A and the thickness of the second polarization layer 50A. Although the nitride semiconductor device 1B in the present embodiment has two spacer layers, the number of the spacer layers may be adjusted according to the performance requirements of the nitride semiconductor device 1B but may not be limited to two and may be one; for example, only one spacer layer is disposed between the first polarization layer 30A and the channel layer 20A. The materials of the first spacer layer 90A and the second spacer layer 100A may be AlN or high Al-content AlGaN.

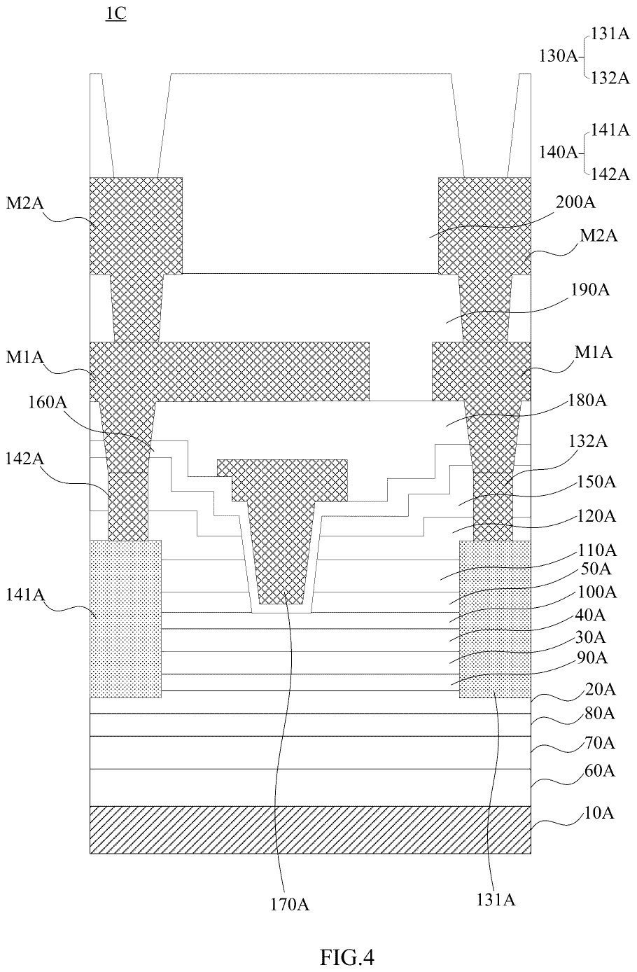

The surface cap layer 110A is disposed on the second polarization layer 50A, and the purpose of the surface cap layer 110A is to prevent epitaxy materials from damaging during manufacture and to provide the great interface with the subsequent first passivation layer 120A (referring to FIG. 4). The material of the surface cap layer 110A may include AlN or GaN. The surface cap layer 110A is the thin layer; the thickness of the surface cap layer 110A is less than the thickness of the second polarization layer 50A.

In the nitride semiconductor device of the present embodiment, the leakage current of the nitride semiconductor device is reduced by the configurations of the buffer layer and the back barrier layer, and the configuration of the spacer layer assists in inducing the 2DEG.

Please refer to FIG. 4, which depicts the cross section diagram of a nitride semiconductor device according to yet embodiment of the present disclosure. As shown in FIG. 4, a nitride semiconductor device 1C includes the substrate 10A, the channel layer 20A, the first polarization layer 30A, the polarization control layer 40A, the second polarization layer 50A, the first buffer layer 60A, the second buffer layer 70A, the back barrier layer 80A, the first spacer layer 90A, the second spacer layer 100A, the surface cap layer 110A, a first passivation layer 120A, a drain electrode 130A, a source electrode 140A, a second passivation layer 150A, a gate insulator layer 160A, a gate electrode 170A, an interlayer dielectric (ILD) layer 180A, a plurality of first metal plugs MIA, an inter-metal dielectric (IMD) layer 190A, a plurality of second metal plug M2A and a third passivation layer 200A. The configuration of the nitride semiconductor device 1C shown in FIG. 4 is similar to the configuration of the nitride semiconductor device 1B shown in FIG. 3, and the similarities between the nitride semiconductor device 1C shown in FIG. 4 and the nitride semiconductor device 1B shown in FIG. 3 would not be repeated.

It should be explained that the first spacer layer 90A, the first polarization layer 30A, the polarization control layer 40A, the second spacer layer 100A, the second polarization layer 50A and the surface cap layer 110A undergo an etching process to constitute a mesa structure after the surface cap layer 110A is formed, and the formation of the mesa structure will be elaborated in the paragraphs corresponding to a manufacturing method of a nitride semiconductor device.

The first passivation layer 120A is disposed on the mesa structure. Specifically, the first passivation layer 120A covers the surface cap layer 110A on the mesa structure and contacts the drain electrode 130A and the source electrode 140A. In other words, the surface cap layer 110A is located between the second polarization layer 50A and the first passivation layer 120A. The second passivation layer 150A is disposed on the first passivation layer 120A and is located on the drain electrode 130A and the source electrode 140A. Specifically, the second passivation layer 150A covers the first passivation layer 120A and contacts the drain electrode 130A and the source electrode 140A. In other words, the first passivation layer 120A is located between the second passivation layer 150A and the surface cap layer 110A. By the configurations of the first passivation layer 120A and the second passivation layer 150A, the surface cap layer 110A and the second polarization layer 50A are prevented from polluting to reduce the leakage current of the nitride semiconductor device and to electrically insulate the drain electrode 130A and the source electrode 140A from each other. Although the nitride semiconductor device 1C in the present embodiment has two passivation layers, the number of the passivation layers may be adjusted according to the performance requirements of the nitride semiconductor device 1C but may not be limited to two and may be one or three. The materials of the first passivation layer 120A and the second passivation layer 150A may include SiNₓ, SiON, SiCN, AlN, SiO₂, AlON or the combination thereof.

The drain electrode 130A and the source electrode 140A are disposed on the opposite two sides of the mesa structure. For example, the drain electrode 130A is disposed on the right side of the mesa structure, while the source electrode 140A is disposed on the left side of the mesa structure. It should be noted that the position of the drain electrode 130A and the position of the source electrode 140A are interchangeable, i.e., the drain electrode 130A is disposed on the left side of the mesa structure, while the source electrode 140A is disposed on the right side of the mesa structure. The drain electrode 130A and the source electrode 140A are all located on the first passivation layer 120A and extends from the first passivation layer 120A to the channel layer 20A. Specifically, the drain electrode 130A and the source electrode 140A protrudes from the upper surface of the first passivation layer 120A, passes through the first passivation layer 120A to extend in a direction toward the substrate 10A, and stops at the channel layer 20A to be connected to the channel layer 20A.

The detailed configurations of the drain electrode 130A and the source electrode 140A will be further described as follows. The drain electrode 130A includes a first extension part 131A and a first electrode part 132A. The first extension part 131A is located on the right side of the mesa structure and extends from the first passivation layer 120A to the channel layer 20A. Still further, the first extension part 131A extends from the lower surface on the right side of the first passivation layer 120A in the direction toward the substrate 10A and stops at the channel layer 20A to contact the channel layer 20A. The first electrode part 132A is disposed on the first extension part 131A and passes through the first passivation layer 120A from a position higher than the upper surface of the first passivation layer 120A to be connected to the first extension part 131A; the second passivation layer 150A contacts the sidewall of the first electrode part 132A. The source electrode 140A includes a second extension part 141A and a second electrode part 142A. The second extension part 141A is located on the left side of the mesa structure and extends from the first passivation layer 120A to the channel layer 20A. Still further, the second extension part 141A extends from the lower surface on the left side of the first passivation layer 120A in the direction toward the substrate 10A and stops at the channel layer 20A to contact the channel layer 20A. The second electrode part 142A is disposed on the second extension part 141A and passes through the first passivation layer 120A from the position higher than the upper surface of the first passivation layer 120A to be connected to the second extension part 141A; the second passivation layer 150A contacts the sidewall of the second electrode part 142A.

In one embodiment, the materials of the first extension part 131A and the second extension part 141A include n-type GaN or n-type InGaN. In another embodiment, the materials of the first extension part 131A and the second extension part 141A include metal materials, and the metal material may include In, Sn, Al, Au, Pt, In, Zn, Ge, Ag, Pb, Pd, Cu, AuBe, BeGe, Ni, PbSn, Cr, AuZn, Ti, W, TiW, TiN or the combination thereof. The materials of the first electrode part 132A and the second extension part 141A are all the metal materials.

In the present embodiment, the second passivation layer 150A has a through hole. The through hole is located between the first extension part 131A and the second extension part 141A and extends to the second spacer layer 100A. Specifically, the through hole extends from the upper surface of the second passivation layer 150A in the direction toward the substrate 10A and stops at the second spacer layer 100A.

The gate insulator layer 160A is disposed on the second passivation layer 150A and one part of the gate insulator layer 160A is disposed in the through hole. Specifically, the gate insulator layer 160A includes a first part and a second part, the first part covers the second passivation layer 150A, and the second part covers the sidewall and the bottom of the through hole. The material of the gate insulator layer 160A includes SiOₓ, SiOC, AlOₓ, HfO₂, Y₂O₃, Y₂TiO₅, Yb₂O₃, ZrO₂, TiO₂, Ta₂O₅ or the combination thereof.

The gate electrode 170A is disposed in the through hole and is electrically insulated from the second spacer layer 100A by the gate insulator layer 160A. Specifically, the gate electrode 170A fills the through hole and contacts the gate insulator layer 160A located on the sidewall and the bottom of the through hole, while one part of the gate electrode 170A is located on the gate insulator layer 160A instead of being located in the through hole. The gate insulator layer 160A located on the second passivation layer 150A partially contacts the gate electrode 170A, and the top and the partial sidewall of the gate electrode 170A does not contact the gate insulator layer 160A. In other words, the gate insulator layer 160A is located between the gate electrode 170A and the second spacer layer 100A and is also located between the gate electrode 170A and the second passivation layer 150A; the gate electrode 170A is isolated from the second polarization layer 50A, the second spacer layer 100A and the surface cap layer 110A by the gate insulator layer 160A. The material of the gate electrode 170A is the metal materials.

By the configurations of the gate insulator layer 160A, the gate electrode 170A, the second polarization layer 50A, the second spacer layer 100A and the surface cap layer 110A, a metal-insulator-semiconductor (MIS) structure is formed to reduce the leakage current of the gate electrode 170A.

The ILD layer 180A is disposed on the gate electrode 170A and is located on the gate insulator layer 160A. Specifically, the ILD layer 180A covers the gate electrode 170A and the partial gate insulator layer 160A and exposes the gate electrode 170A, the drain electrode 130A and the source electrode 140A; the gate insulator layer 160A is located between the ILD layer 180A and the second passivation layer 150A. Still further, the ILD layer 180A covers the top of the gate electrode 170A and partially exposes the top of the drain electrode 130A and the top of the source electrode 140A. The material of the ILD layer 180A is the same as the material of the gate insulator layer 160A and would not be repeated.

The plurality of first metal plugs MIA is disposed on the ILD layer 180A and passes through the ILD layer 180A, the gate insulator layer 160A and the second passivation layer 150A to be connected to the drain electrode 130A and the source electrode 140A. It should be noted that the first metal plug MIA connected to the source electrode 140A is located on the side of the ILD layer 180A close to the source electrode 140A and extends toward the gate electrode 170A to form a source gate field plate. The source gate field plate shades the gate electrode 170A, i.e., the projection of the source gate field plate on the substrate 10A overlaps the projection of the gate electrode 170A on the substrate 10A, but the source gate field plate does not contact the first metal plug MIA connected to the drain electrode 130A. There is the ILD layer 180A between two adjacent first metal plugs MIA; by the ILD layer 180A, two adjacent first metal plugs MIA are electrically insulated from each other. For example, the number of the first metal plugs MIA is two, and two first metal plugs MIA are respectively connected to the drain electrode 130A and the source electrode 140A; the first metal plug MIA connected to the drain electrode 130A and the first metal plug MIA connected to the source electrode 140A are electrically insulated from the gate electrode 170A by the ILD layer 180A.

It should be explained that the number of the first metal plugs MIA may be adjusted according to the performance requirements but may not be limited to two although the number of the first metal plugs MIA shown in FIG. 4 is two. The materials of the first metal plugs MIA are the metal materials.

The IMD layer 190A is disposed on the ILD layer 180A. Specifically, the IMD layer 190A covers the ILD layer 180A, partially covers the tops of the first metal plugs MIA, and partially exposes the tops of the first metal plugs MIA. There is the IMD layer 190A between two adjacent first metal plugs MIA. In other words, the IMD layer 190A contacts the first metal plugs MIA, and the first metal plugs MIA are electrically insulated from each other by the IMD layer 190A. The material of the IMD layer 190A is the same as the material of the gate insulator layer 160A and would not be repeated.

The plurality of second metal plugs M2A is disposed on the IMD layer 190A and pass through the IMD layer 190A to be connected to the first metal plugs MIA. There is the IMD layer 190A between two adjacent second metal plugs M2A; by the IMD layer 190A, two adjacent second metal plugs M2A are electrically insulated from each other. Still further, the second metal plugs M2A contacts the IMD layer 190A and are electrically insulated from each other by the IMD layer 190A. The number of the second metal plugs M2A is the same as the number of the first metal plugs M1A.

It should be explained that the number of the second metal plugs M2A may be adjusted according to the performance requirements but may not be limited to two although the number of the second metal plugs M2A shown in FIG. 4 is two. The materials of the second metal plugs M2A are the metal materials.

The third passivation layer 200A is disposed on the IMD layer 190A and exposes the second metal plugs M2A. Specifically, the third passivation layer 200A covers the IMD layer 190A, partially covers the tops of the second metal plugs M2A, and partially exposes the tops of the second metal plugs M2A. Ther is the third passivation layer 200A between two adjacent second metal plugs M2A. In other words, the third passivation layer 200A contacts the second metal plugs M2A, and the second metal plugs M2A are electrically insulated from each other by the third passivation layer 200A. The types of the material of the third passivation layer 200A are the same as the types of the material of the first passivation layer 120A and would not be repeated; however, the selection of the material of the third passivation layer 200A may be different from the selection of the material of the first passivation layer 120A, and for example, the material of the first passivation layer 120A is AlN, while the material of the third passivation layer 200A is SiO₂.

In the nitride semiconductor device of the present embodiment, the leakage current of the nitride semiconductor device is reduced by the passivation layers, and the threshold voltage of the nitride semiconductor device is adjusted by the configurations of the gate electrode with the MIS structure, the drain electrode, the source electrode and the dielectric layers, thereby improving the performance of the nitride semiconductor device.

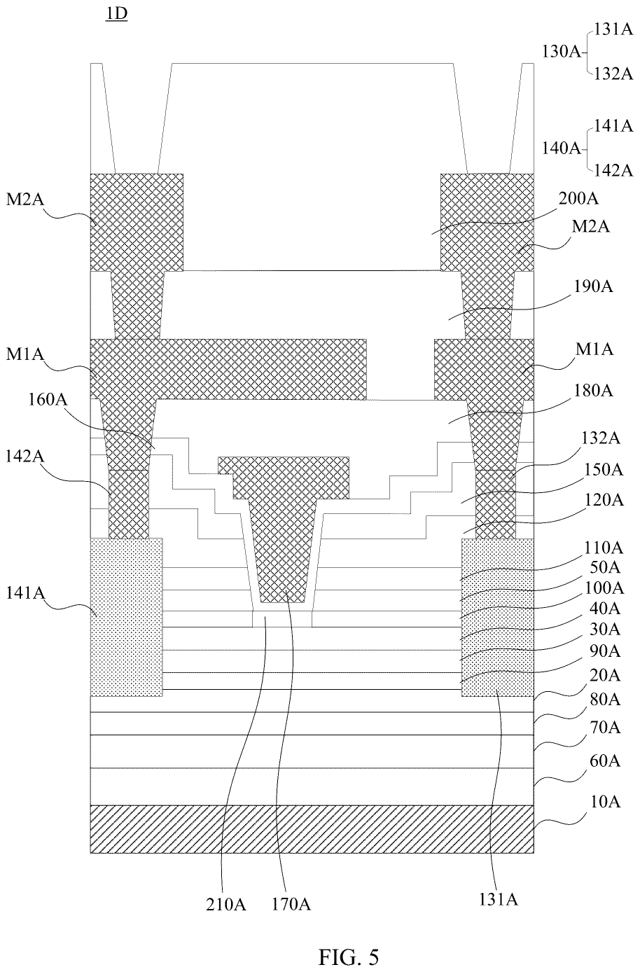

Please refer to FIG. 5, which depicts the cross section diagram of a nitride semiconductor device according to still embodiment of the present disclosure. As shown in FIG. 5, a nitride semiconductor device 1D includes the substrate 10A, the channel layer 20A, the first polarization layer 30A, the polarization control layer 40A, the second polarization layer 50A, the first buffer layer 60A, the second buffer layer 70A, the back barrier layer 80A, the first spacer layer 90A, the second spacer layer 100A, the surface cap layer 110A, the first passivation layer 120A, the drain electrode 130A, the source electrode 140A, the second passivation layer 150A, the gate insulator layer 160A, the gate electrode 170A, the ILD layer 180A, the plurality of first metal plug MIA, the IMD layer 190A, the plurality of second metal plug M2A, the third passivation layer 200A and oxide layer 210A. The configuration of the nitride semiconductor device 1D shown in FIG. 5 is similar to the configuration of the nitride semiconductor device 1C shown in FIG. 4, and the similarities between the nitride semiconductor device 1D shown in FIG. 5 and the nitride semiconductor device 1C shown in FIG. 4 would not be repeated.

The oxide layer 210A is disposed on the bottom of the through hole of the second passivation layer 150A, and the gate insulator layer 160A is located on the oxide layer 210A. Specifically, the oxide layer 210A is formed after the through hole of the second passivation layer 150A is formed, and the time point of the formation of the oxide layer 210A precedes the time point of the formation of the gate insulator layer 160A; the oxide layer 210A contacts the second spacer layer 100A. The types of the material of the oxide layer 210A are the same as the types of the material of the gate insulator layer 160A and would not be repeated; however, the selection of the material of the oxide layer 210A may be different from the selection of the material of the gate insulator layer 160A, and for example, the material of the gate insulator layer 160A is SiOₓ, while the material of the oxide layer 210A is AlON.

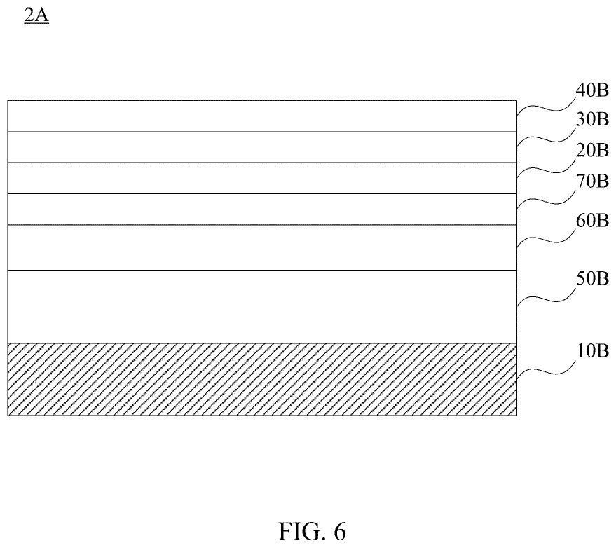

Please refer to FIG. 6 depicts the cross section diagram of a nitride semiconductor device according to yet another embodiment of the present disclosure. As shown in FIG. 6, a nitride semiconductor device 2A includes a substrate 10B, a channel layer 20B, a spacer layer 30B and a polarization layer 40B. The configurations of the substrate 10B and the channel layer 20B are similar to the configurations of the substrate 10A and the channel layer 20A shown in FIG. 1, and the resemblances between the FIG. 6 and FIG. 1 would not be repeated.

The spacer layer 30B is disposed on the channel layer 20B, and the polarization layer 40B is disposed on the spacer layer 30B; in other words, the spacer layer 30B is located between the polarization layer 40B and the channel layer 20B. The spacer layer 30B is the thin layer; the thickness of the spacer layer 30B is less than the thickness of the channel layer 20B and the thickness of the polarization layer 40B.

The lattice constant of the polarization layer 40B is less than the lattice constant of the channel layer 20B, and the bandgap of the polarization layer 40B is greater than the bandgap of the channel layer 20B. Because the bandgap of the polarization layer 40B is different from the bandgap of the channel layer 20B, the energy band at the boundary between the polarization layer 40B and the channel layer 20B bends, and thus, the triangular quantum well structure is formed. The triangular quantum well structure results in generating the 2DEG at the boundary between the spacer layer 30B and the channel layer 20B.

The material of the polarization layer 40B may include GaN, AlGaN, InAlN, AlN, ScGaN, ScAlN, BN, AlInGaN or InGaN. The material of the spacer layer 30B may include AlN or high Al-content AlGaN.

In the nitride semiconductor device of the present embodiment, only one polarization layer 40B and the channel layer 20B is utilized to generate the 2DEG without the polarization control layer, and the size of the nitride semiconductor device may be further reduced.

In the nitride semiconductor device of the present embodiment, by the configurations of the polarization control layer and the second polarization layer, the positive polarization charges accumulating at the boundary between the channel layer 20A and the first polarization layer 30A are affected, thereby controlling the generation of the 2DEG.

In the present embodiment, the nitride semiconductor device 2A further includes a first buffer layer 50B, a second buffer layer 60B and a back barrier layer 70B. The configurations of the first buffer layer 50B, the second buffer layer 60B and the back barrier layer 70B are the same as the configurations of the first buffer layer 60A, the second buffer layer 70A and the back barrier layer 80A shown in FIG. 3 and would not be repeated.

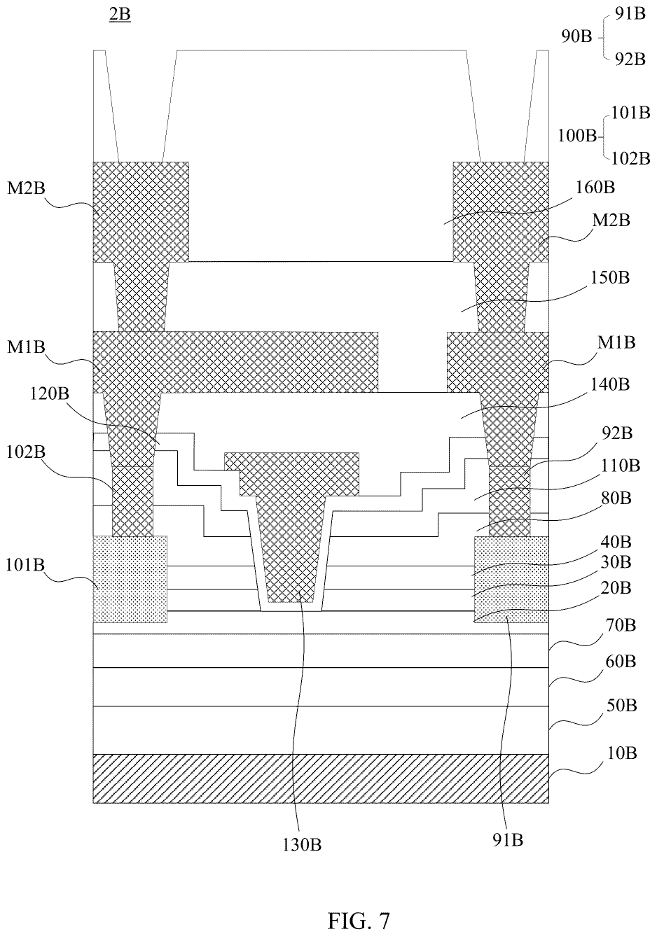

Based on the nitride semiconductor device 2A shown in FIG. 6, the nitride semiconductor device 2B shown in FIG. 7 adds the configurations of a first passivation layer 80B, a drain electrode 90B, a source electrode 100B, a second passivation layer 110B, a gate insulator layer 120B, a gate electrode 130B, an ILD layer 140B, a plurality of first metal plugs M1B, an IMD layer 150B, a plurality of second metal plugs M2B and a third passivation layer 160B. The configurations of the first passivation layer 80B, the drain electrode 90B, the source electrode 100B, the second passivation layer 110B, the gate insulator layer 120B, the gate electrode 130B, the ILD layer 140B, the first metal plugs M1B, the IMD layer 150B, the second metal plugs M2B and the third passivation layer 160B are similar to the configurations of the first passivation layer 120A, the drain electrode 130A, the source electrode 140A, the second passivation layer 150A, the gate insulator layer 160A, the gate electrode 170A, the ILD layer 180A, the first metal plugs MIA, the IMD layer 190A, the second metal plug M2A and the third passivation layer 200A shown in FIG. 4 and would not be repeated.

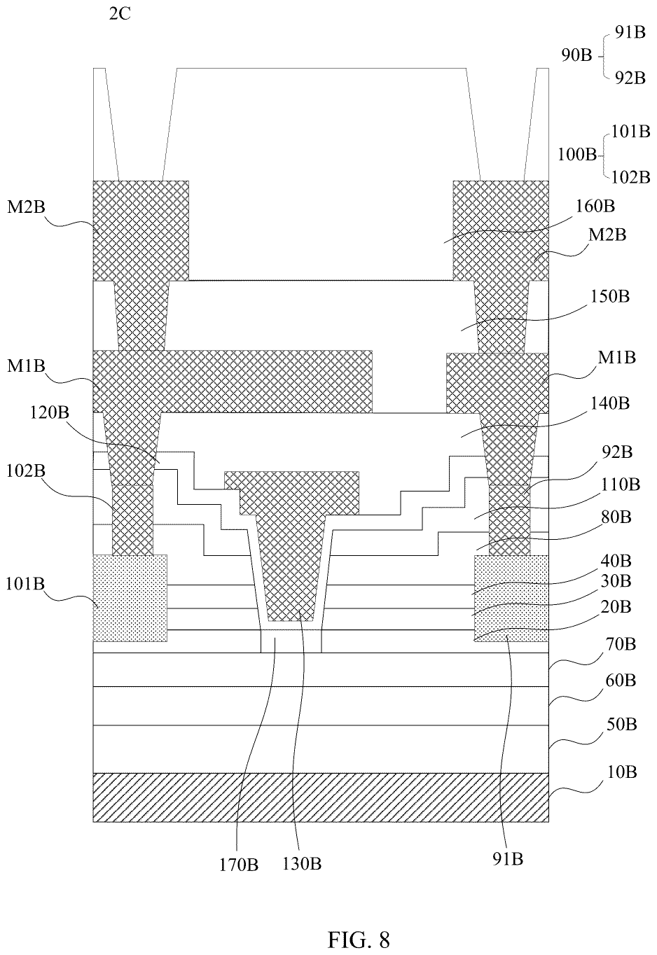

Based on the nitride semiconductor device 2A shown in FIG. 6, the nitride semiconductor device 2C shown in FIG. 8 adds the configurations of the first passivation layer 80B, the drain electrode 90B, the source electrode 100B, the second passivation layer 110B, the gate insulator layer 120B, the gate electrode 130B, the ILD layer 140B, the plurality of first metal plugs M1B, the IMD layer 150B, the plurality of second metal plugs M2B, the third passivation layer 160B and an oxide layer 170B. The configurations of the first passivation layer 80B, the drain electrode 90B, the source electrode 100B, the second passivation layer 110B, the gate insulator layer 120B, the gate electrode 130B, the ILD layer 140B, the first metal plugs M1B, the IMD layer 150B, the second metal plugs M2B, the third passivation layer 160B and the oxide layer 170B are similar to the configurations of the first passivation layer 120A, the drain electrode 130A, the source electrode 140A, the second passivation layer 150A, the gate insulator layer 160A, the gate electrode 170A, the ILD layer 180A, the first metal plugs MIA, the IMD layer 190A, the second metal plugs M2A, the third passivation layer 200A and the oxide layer 210A shown in FIG. 5 and would not be repeated.

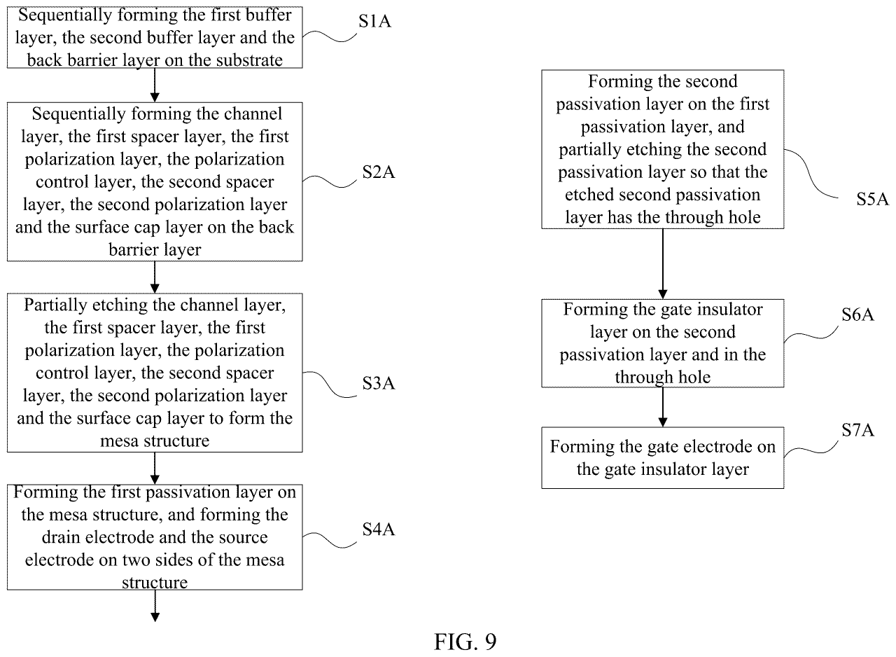

Please refer to FIG. 9, which depicts the flowchart of a manufacturing method of a nitride semiconductor device according to one embodiment of the present disclosure. As shown in FIG. 9, a manufacturing method of a nitride semiconductor device includes step S1A to step S7A.

Step S1A: sequentially forming the first buffer layer 60A, the second buffer layer 70A and the back barrier layer 80A on the substrate 10A. The method of forming the first buffer layer 60A, the second buffer layer 70A and the back barrier layer 80A may be chemical vapor deposition (CVD), molecular beam epitaxy (MBE), atomic layer deposition (ALD) or sputtering.

Step S2A: sequentially forming the channel layer 20A, the first spacer layer 90A, the first polarization layer 30A, the polarization control layer 40A, the second spacer layer 100A, the second polarization layer 50A and the surface cap layer 110A on the back barrier layer 80A. The method of forming the channel layer 20A, the first spacer layer 90A, the first polarization layer 30A, the polarization control layer 40A, the second spacer layer 100A, the second polarization layer 50A and the surface cap layer 110A may be the same as the method of forming the first buffer layer 60A, the second buffer layer 70A and the back barrier layer 80A.

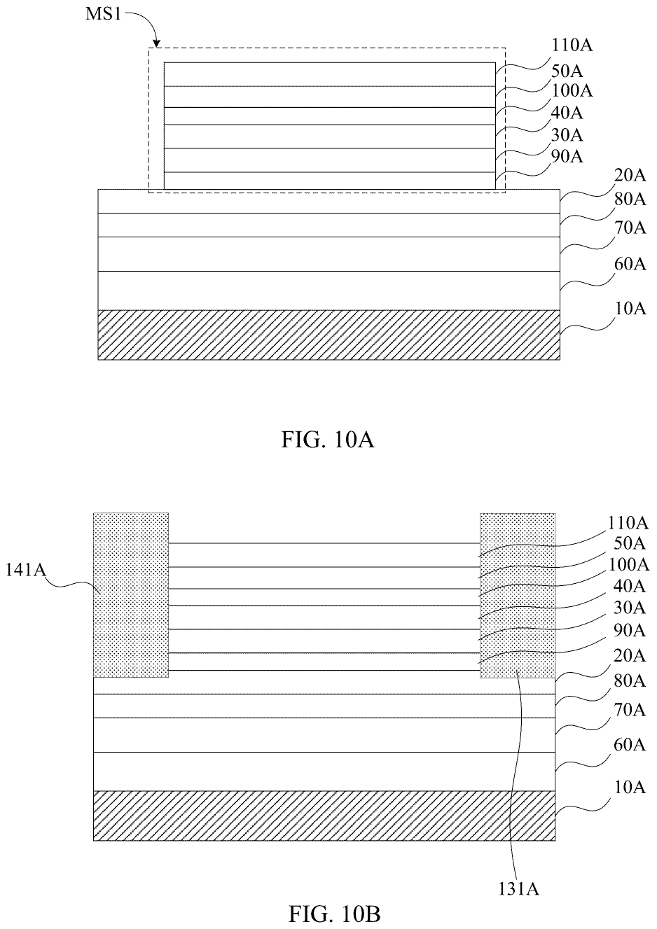

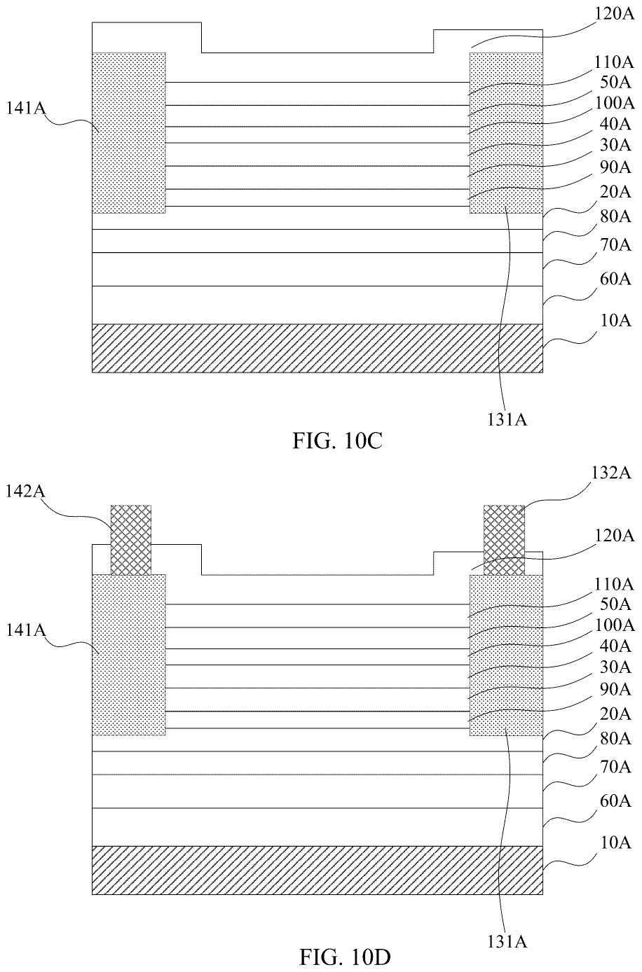

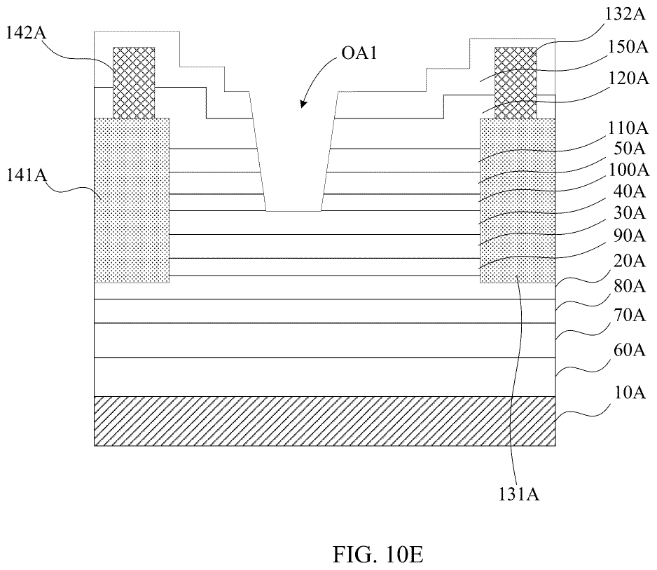

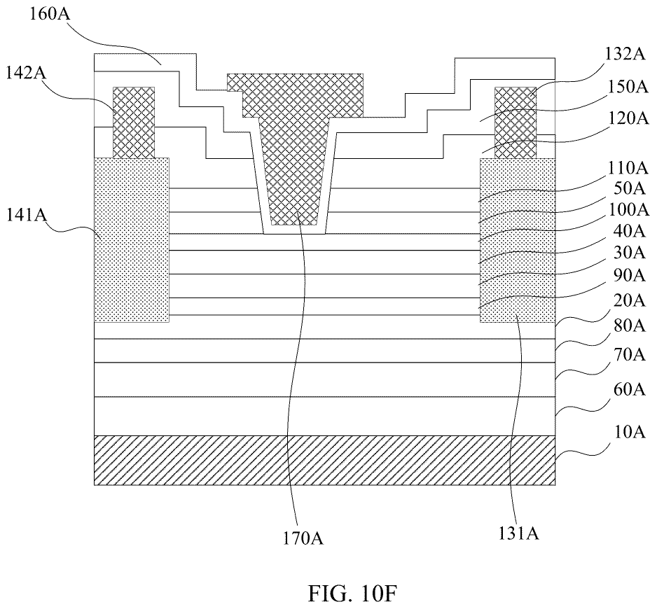

Step S3A: partially etching the channel layer 20A, the first spacer layer 90A, the first polarization layer 30A, the polarization control layer 40A, the second spacer layer 100A, the second polarization layer 50A and the surface cap layer 110A to form the mesa structure MS1. Specifically, a first patterned photoresist layer is first formed on the surface cap layer 110A, and based on the first patterned photoresist layer, the channel layer 20A, the first spacer layer 90A, the first polarization layer 30A, the polarization control layer 40A, the second spacer layer 100A, the second polarization layer 50A and the surface cap layer 110A are partially etched by inductively coupled plasma-reactive ion etching (ICP-RIE) or wet etching to expose the channel layer 20A; afterwards, the mesa structure MS1 is formed as shown in FIG. 10A, and the first patterned photoresist layer is removed.

Step S4A: forming the first passivation layer 120A on the mesa structure MS1, and forming the drain electrode 130A and the source electrode 140A on two sides of the mesa structure MS1. The drain electrode 130A includes the first extension part 131A and the first electrode part 132A, and the source electrode 140A includes the second extension part 141A and the second electrode part 142A.

Specifically, the first extension part 131A and the second extension part 141A are first formed on two sides of the mesa structure MS1, and then the first passivation layer 120A is formed on the mesa structure MS1, and the first passivation layer 120A is partially etched to expose the first extension part 131A and second extension part 141A, thereby defining a drain electrode region and a source electrode region. Finally, the first electrode part 132A and the second electrode part 142A are respectively formed on the drain electrode region and the source electrode region.

In one embodiment, the materials of the first extension part 131A and the second extension part 141A include n-type GaN or n-type InGaN, and the method of forming the first extension part 131A and the second extension part 141A is the same as the method of forming the first buffer layer 60A, the second buffer layer 70A and the back barrier layer 80A. A case that the method of forming the first extension part 131A and the second extension part 141A is CVD and the materials of the first extension part 131A and the second extension part 141A are n-type GaN would be taken as an example to elaborate step S4A as follows.

A n-type GaN thin film is formed on the mesa structure MS1 by CVD, the n-type GaN thin film covers the top of the mesa structure MS1 and the sidewalls of two sides of the mesa structure MS1 and is partially etched, and the n-type GaN thin film as shown in FIG. 10B is left to serve as the first extension part 131A and the second extension part 141A. Next, the first passivation layer 120A is formed as shown in FIG. 10C and covers the first extension part 131A, the second extension part 141A and the top of the mesa structure MS1, wherein the method of forming the first passivation layer 120A is the same as the method of forming the first buffer layer 60A, the second buffer layer 70A and the back barrier layer 80A. Afterwards, a second patterned photoresist layer is formed on the first passivation layer 120A, and based on the second patterned photoresist layer, the first passivation layer 120A is partially etched to expose the top of the first extension part 131A and the top of the second extension part 141A, thereby defining the drain electrode region and the source electrode region. Finally, the first electrode part 132A and the second electrode part 142A are respectively formed on the drain electrode region and the source electrode region as shown in FIG. 10D, and the second patterned photoresist layer is removed, wherein the method of forming the first electrode part 132A and the second electrode part 142A may be CVD, sputtering or evaporation. The first extension part 131A and the first electrode part 132A constitute the drain electrode 130A, and the second extension part 141A and the second electrode part 142A constitute the source electrode 140A.

In another embodiment, the materials of the first extension part 131A and the second extension part 141A include the metal materials, and the method of forming the first extension part 131A and the second extension part 141A is the same as the method of forming the first electrode part 132A and the second electrode part 142A.

A first metal layer is first formed on the mesa structure MS1 and covers the top of the mesa structure MS1 and the sidewalls of two sides of the mesa structure MS1, an auxiliary layer with an opening is formed on the first metal layer, the first metal layer is partially etched, and the first metal layer as shown in FIG. 10B is left to serve as the first extension part 131A and the second extension part 141A. Next, the first passivation layer 120A is formed as shown in FIG. 10C and covers the first extension part 131A, the second extension part 141A and the top of the mesa structure MS1. Afterwards, an auxiliary layer with two openings is formed on the first passivation layer 120A, and based on the auxiliary layer with two openings, the first passivation layer 120A partially etched to expose the top of the first extension part 131A and the top of the second extension part 141A, thereby defining the drain electrode region and the source electrode region, wherein the material of the auxiliary layer may include SiOₓ, SiNₓ, SiON, SiCN, SiOC, AlOₓ, HfO₂ or the combination thereof. Finally, the first electrode part 132A and the second electrode part 142A are respectively formed on the drain electrode region and the source electrode region as shown in FIG. 10D, and the auxiliary layer is removed. The first extension part 131A and the first electrode part 132A constitute the drain electrode 130A, and the second extension part 141A and the second electrode part 142A constitute the source electrode 140A.

In yet another embodiment, the first passivation layer 120A is first formed on the mesa structure MS1 and the channel layer 20A, and the first passivation layer 120A on the channel layer 20A is etched. Afterwards, the first metal layer is formed on the first passivation layer 120A and the channel layer 20A by sputtering or evaporation, and high-temperature thermal annealing is performed on the first metal layer. The annealed first metal layer moves from the surface of the first passivation layer 120A to the two sides of the mesa structure MS1 to contact the channel layer 20A.

Step S5A: forming the second passivation layer 150A on the first passivation layer 120A, and partially etching the second passivation layer 150A so that the etched second passivation layer 150A has the through hole OA1. Specifically, the second passivation layer 150A is formed on the first passivation layer 120A and covers the first electrode part 132A and the second electrode part 142A; the method of forming the second passivation layer 150A is the same as the method of forming the first buffer layer 60A, the second buffer layer 70A and the back barrier layer 80A. Afterwards, a third patterned photoresist layer is formed on the second passivation layer 150A, and based on the third patterned photoresist layer, the second passivation layer 150A, the first passivation layer 120A, the surface cap layer 110A and the second polarization layer 50A are partially etched and stop being etched at the second spacer layer 100A to form the through hole OA1 as shown in FIG. 10E. In other words, the second spacer layer 100A serves as an etch stop layer.

Step S6A: forming the gate insulator layer 160A on the second passivation layer 150A and in the through hole OA1. As shown in FIG. 10F, the gate insulator layer 160A covers the upper surface of the second passivation layer 150A and the sidewall and the bottom of the through hole OA1. The method of forming the gate insulator layer 160A is the same as the method of forming the first buffer layer 60A, the second buffer layer 70A and the back barrier layer 80A.

Step S7A: forming the gate electrode 170A on the gate insulator layer 160A. Specifically, a second metal layer is formed on the gate insulator layer 160A, fills the through hole OA1 and covers the gate insulator layer 160A, wherein the method of forming the second metal layer is the same as the method of forming the first electrode part 132A and the second electrode part 142A. Afterwards, the second metal layer is partially etched to expose the upper surface of the partial gate insulator layer 160A, and the second metal layer as shown in FIG. 10F is left to serve as the gate electrode 170A.

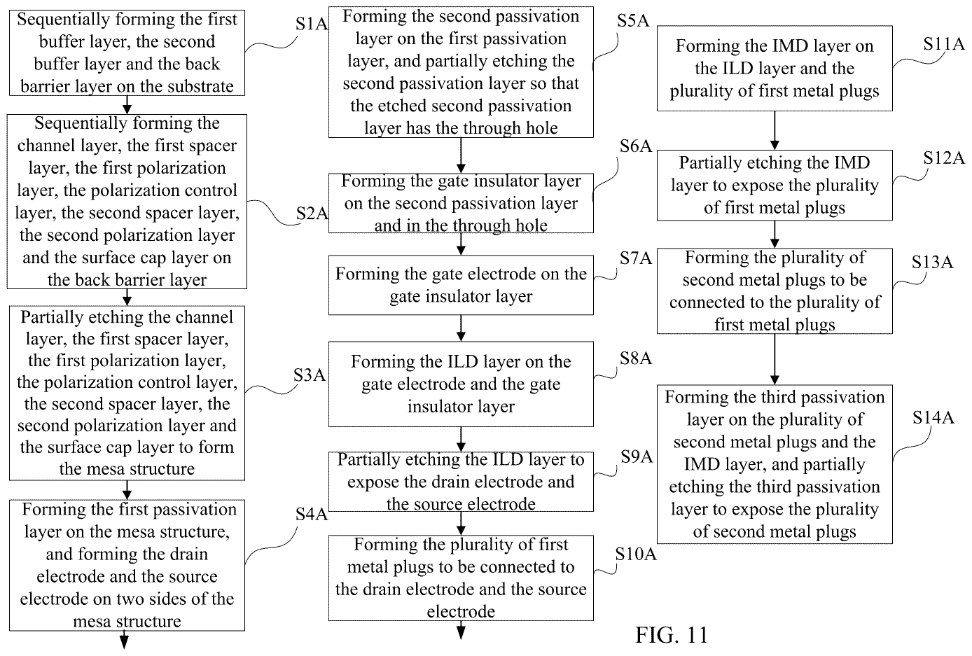

Please refer to FIG. 11, which depicts the flowchart of a manufacturing method of a nitride semiconductor device according to another embodiment of the present disclosure. As shown in FIG. 11, a manufacturing method of a nitride semiconductor device includes step S1A to step S14A; step S1A to step S7A shown in FIG. 11 are the same as step S1A to step S7A shown in FIG. 9 and would not be repeated.

Step S8A: forming the ILD layer 180A on the gate electrode 170A and the gate insulator layer 160A. The ILD layer 180A covers the gate electrode 170A and the gate insulator layer 160A. The method of forming the ILD layer 180A is the same as the method of forming the first buffer layer 60A, the second buffer layer 70A and the back barrier layer 80A.

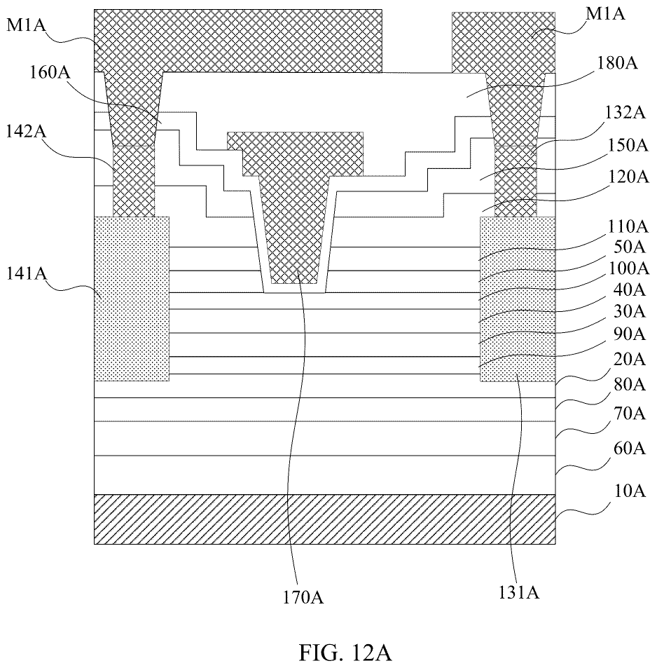

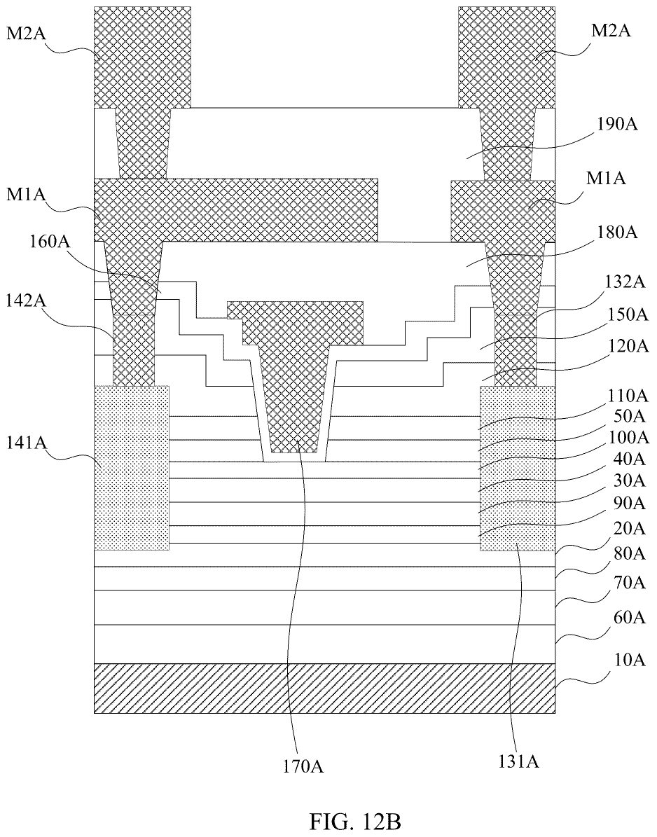

Step S9A: partially etching the ILD layer 180A to expose the drain electrode 130A and the source electrode 140A. Specifically, a fourth patterned photoresist layer is formed on the ILD layer 180A, and based on the fourth patterned photoresist layer, the ILD layer 180A is partially etched to form two openings. As shown in FIG. 12A, two openings of the ILD layer 180A expose the drain electrode 130A and the source electrode 140A.

Step S10A: forming the plurality of first metal plugs MIA to be connected to the drain electrode 130A and the source electrode 140A. As shown in FIG. 12A, in conjunction with a metal mask, two first metal plugs MIA are formed to be connected to the drain electrode 130A and the source electrode 140A, wherein the first metal plug M1A connected to the source electrode 140A extends from the source electrode 140A to the gate electrode 170A. The method of forming the first metal plugs MIA is the same as the method of forming the first electrode part 132A and the second electrode part 142A.

Step S11A: forming the IMD layer 190A on the ILD layer 180A and the plurality of first metal plugs MIA. The IMD layer 190A covers the ILD layer 180A and the first metal plugs MIA. The method of forming the IMD layer 190A is the same as the method of forming the first buffer layer 60A, the second buffer layer 70A and the back barrier layer 80A.

Step S12A: partially etching the IMD layer 190A to expose the plurality of first metal plugs MIA. Specifically, the fourth patterned photoresist layer is formed on the IMD layer 190A, and based on the fourth patterned photoresist layer, the IMD layer 190A is partially etched to form two openings. As shown in FIG. 12B, two openings of the IMD layer 190A expose two first metal plugs MIA.

Step S13A: forming the plurality of second metal plugs M2A to be connected to the plurality of first metal plugs MIA. As shown in FIG. 12B, in conjunction with the metal mask, two second metal plugs M2A are formed to be connected to two first metal plugs MIA. The method of forming the second metal plugs M2A is the same as the method of forming the first electrode part 132A and the second electrode part 142A.

Step S14A: forming the third passivation layer 200A on the plurality of second metal plugs M2A and the IMD layer 190A, and partially etching the third passivation layer 200A to expose the plurality of second metal plugs M2A. Specifically, the fourth patterned photoresist layer is formed on the third passivation layer 200A, and based on the fourth patterned photoresist layer, the third passivation layer 200A is partially etched to form two openings. As shown in FIG. 12B, two openings of the third passivation layer 200A expose two second metal plugs M2A. The method of forming the third passivation layer 200A is the same as the method of forming the first buffer layer 60A, the second buffer layer 70A and the back barrier layer 80A.

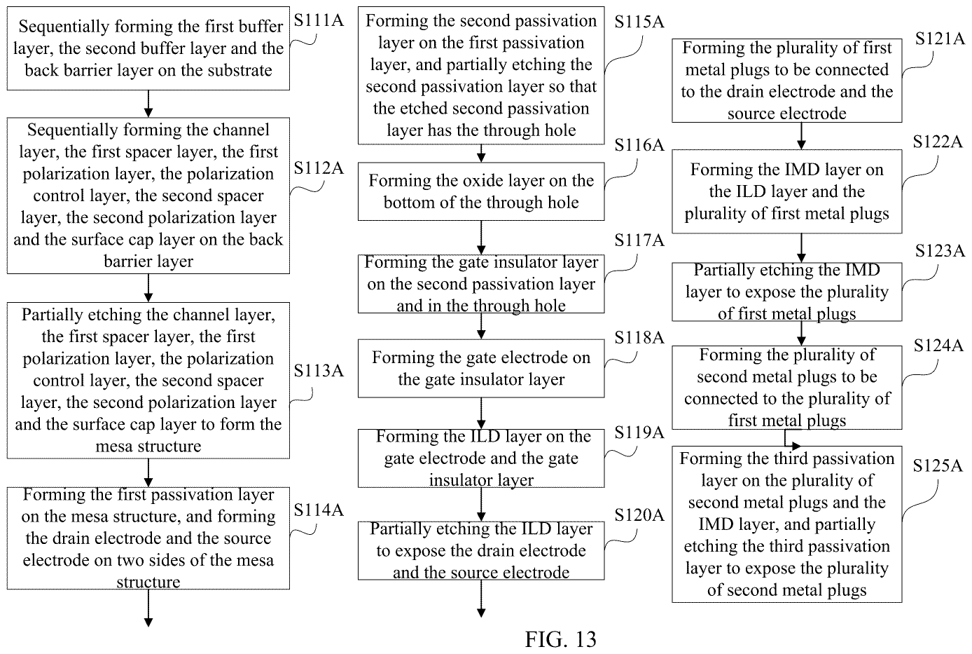

Please refer to FIG. 13, which depicts the flowchart of a manufacturing method of a nitride semiconductor device according to yet embodiment of the present disclosure. As shown in FIG. 13, a manufacturing method of a nitride semiconductor device includes step S111A to step S125A; step S111A to step S115A and step S117A to step S125A shown in FIG. 13 are the same as step S1A to step S14A shown in FIG. 11 and would not be repeated.

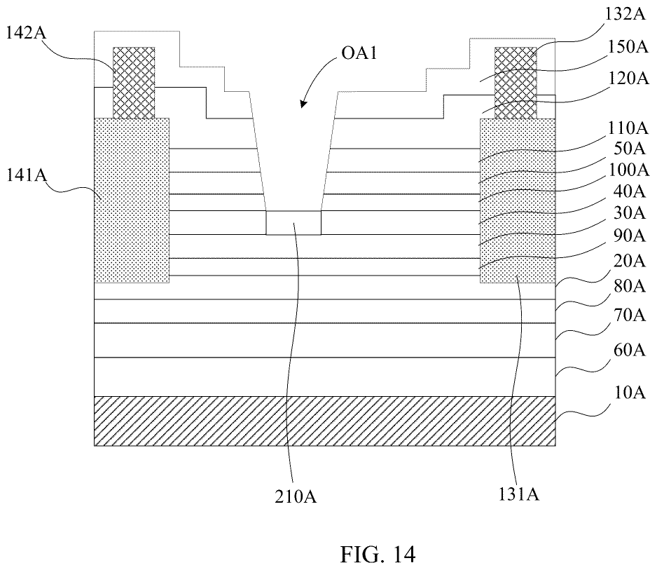

Step S116A: forming the oxide layer 210A on the bottom of the through hole OA1. As shown in FIG. 14, the oxide layer 210A has an ability to eliminate the surface defects of the etched second spacer layer 100A. The method of forming the oxide layer 210A is the same as the method of forming the first buffer layer 60A, the second buffer layer 70A and the back barrier layer 80A.

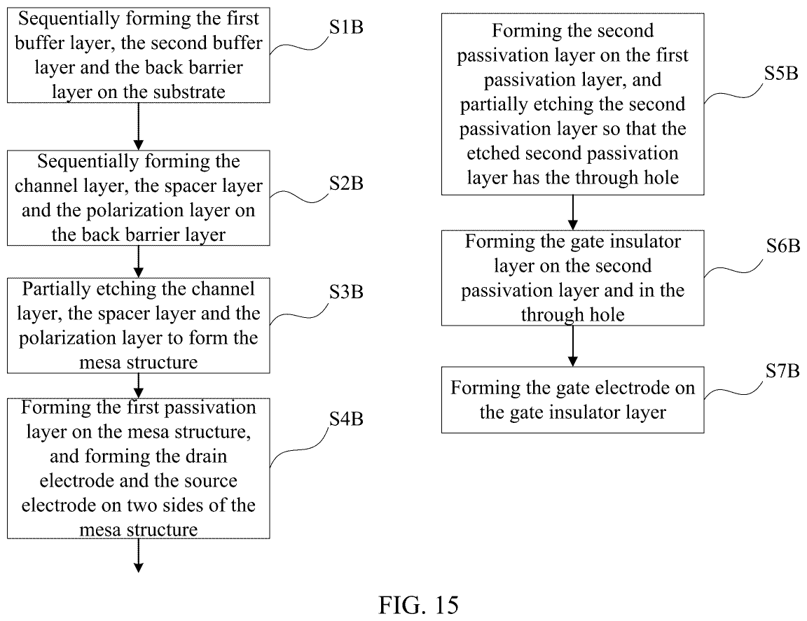

Please refer to FIG. 15, which depicts the flowchart of a manufacturing method of a nitride semiconductor device according to still embodiment of the present disclosure. As shown in FIG. 15, a manufacturing method of a nitride semiconductor device includes step S1B to step S7B.

Step S1B: sequentially forming the first buffer layer 50B, the second buffer layer 60B and the back barrier layer 70B on the substrate 10A. The method of forming the first buffer layer 50B, the second buffer layer 60B and the back barrier layer 70B may be CVD, MBE, ALD or sputtering.

Step S2B: sequentially forming the channel layer 20B, the spacer layer 30B and the polarization layer 40B on the back barrier layer 70B. The method of forming the channel layer 20B, the spacer layer 30B and the polarization layer 40B is the same as the method of forming the first buffer layer 50B, the second buffer layer 60B and the back barrier layer 70B.

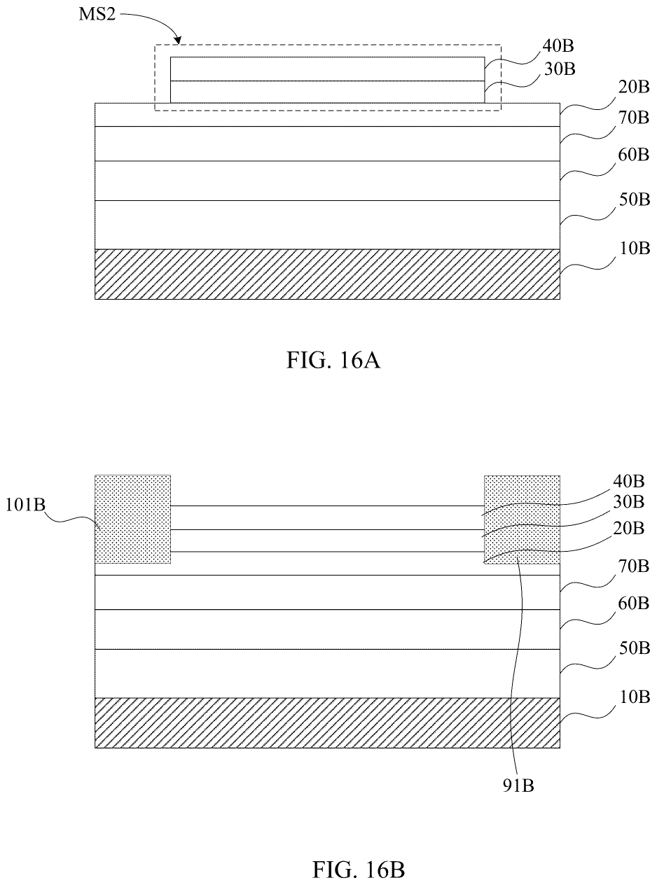

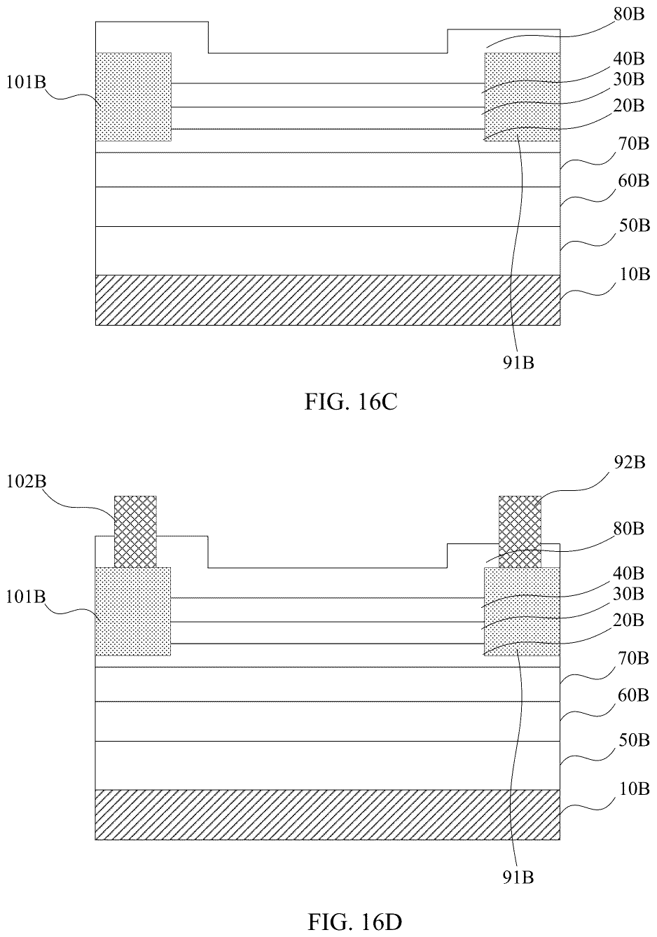

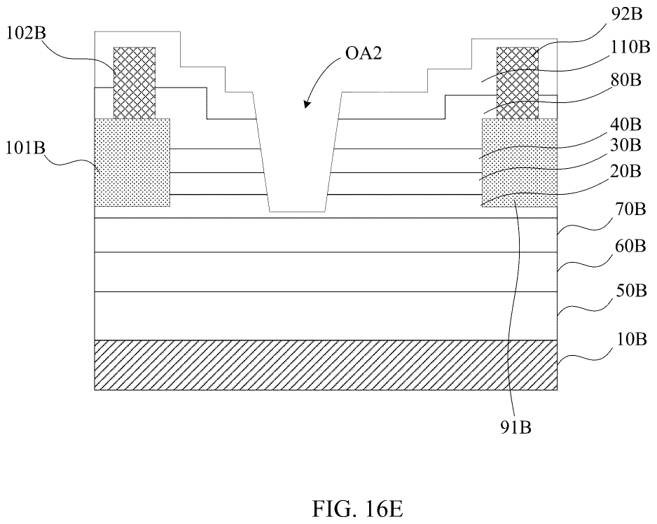

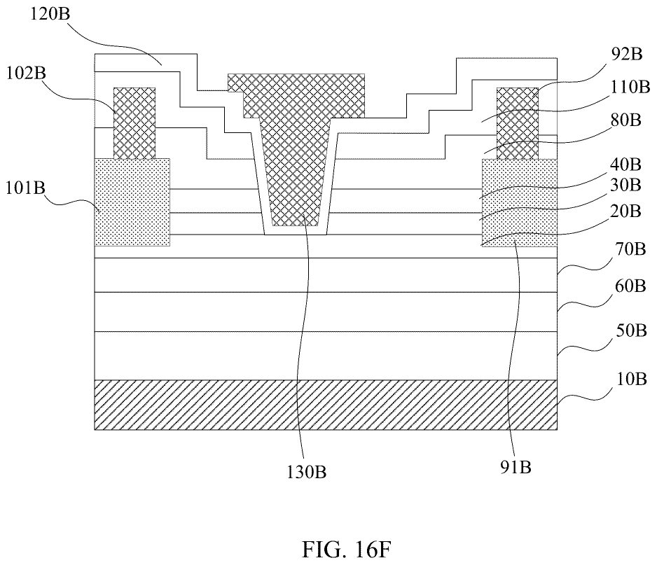

Step S3B: partially etching the channel layer 20B, the spacer layer 30B and the polarization layer 40B to form the mesa structure MS2. Specifically, the first patterned photoresist layer is first formed on the polarization layer 40B, and based on the first patterned photoresist layer, the channel layer 20B, spacer layer 30B and the polarization layer 40B are partially etched by ICP-RIE or wet etching to expose the channel layer 20A; afterwards, the mesa structure MS2 is formed as shown in FIG. 16A, and the first patterned photoresist layer is removed.

Step S4B: forming the first passivation layer 80B on the mesa structure MS2, and forming the drain electrode 90B and the source electrode 100B on two sides of the mesa structure MS2. The drain electrode 90B includes the first extension part 91B and the first electrode part 92B, and the source electrode 100B includes the second extension part 101B and the second electrode part 102B.

As shown in FIG. 16B, the first extension part 91B and the second extension part 101B are first formed on two sides of the mesa structure MS2. Afterwards, as shown in FIG. 16C and FIG. 16D, the first passivation layer 80B is formed on the mesa structure MS2, and the first passivation layer 80B is partially etched to expose the first extension part 91B and second extension part 101B, thereby defining the drain electrode region and the source electrode region. Finally, the first electrode part 92B and the second electrode part 102B are respectively formed on the drain electrode region and the source electrode region. The details of step S4B shown in FIG. 15 is the same as the details of step S4A shown in FIG. 9, and the only difference between step S4B shown in FIG. 15 and step S4A shown in FIG. 9 is the different reference numbers.

Step S5B: forming the second passivation layer 110B on the first passivation layer 80B, and partially etching the second passivation layer 110B so that the etched second passivation layer 110B has the through hole OA2. Specifically, the second passivation layer 110B is formed on the first passivation layer 80B and covers the first electrode part 92B and the second electrode part 102B; the method of forming the second passivation layer 110B is the same as the method of forming the first buffer layer 50B, the second buffer layer 60B and the back barrier layer 70B.

Afterwards, the third patterned photoresist layer is formed on the second passivation layer 110B, and based on the third patterned photoresist layer, the second passivation layer 110B, the first passivation layer 80B and the spacer layer 30B are partially etched and stop being etched at the spacer layer 30B to form the through hole OA2 as shown in FIG. 16E. In other words, the spacer layer 30B serves as the etch stop layer.

Step S6B: forming the gate insulator layer 120B on the second passivation layer 110B and in the through hole OA2. As shown in FIG. 16F, the gate insulator layer 160A covers the upper surface of the second passivation layer 110B and the sidewall and the bottom of the through hole OA2. The method of forming the gate insulator layer 120B is the same as the method of forming the first buffer layer 50B, the second buffer layer 60B and the back barrier layer 70B.

Step S7B: forming the gate electrode 130B on the gate insulator layer 120B. Specifically, the second metal layer is formed on the gate insulator layer 160A, fills the through hole OA2 and covers the gate insulator layer 120B, wherein the method of forming the second metal layer may be CVD, sputtering or evaporation. Afterwards, the second metal layer is partially etched to expose the upper surface of the partial gate insulator layer 120B, and the second metal layer as shown in FIG. 16F is left to serve as the gate electrode 130B.

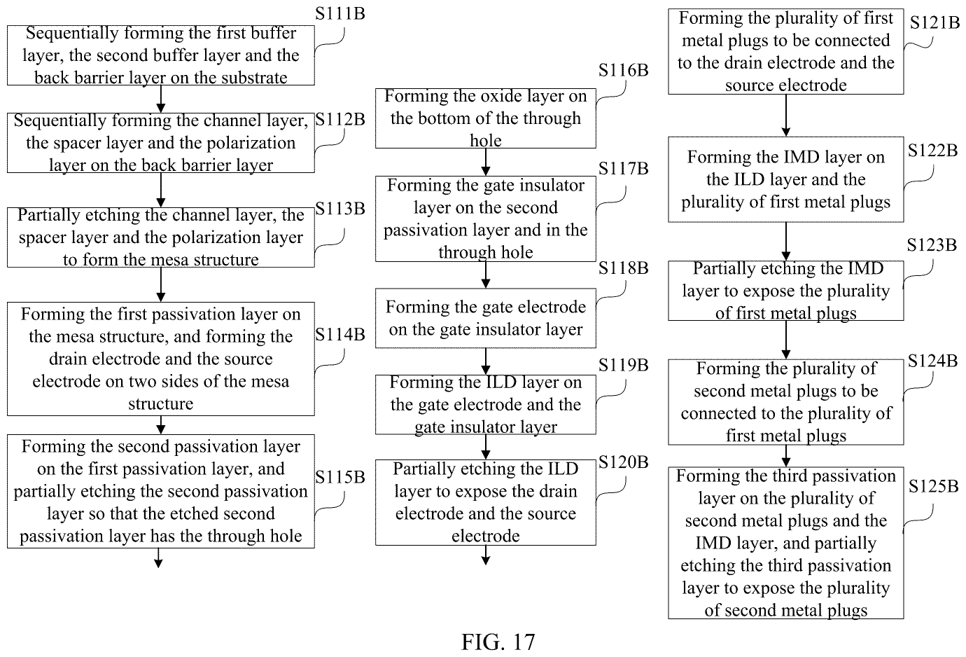

Based on the manufacturing method of the nitride semiconductor device shown in FIG. 15, a manufacturing method of a nitride semiconductor device shown in FIG. 17 adds step S116B and step S119B to step S125B. Step S116B and step S119B to step S125B shown in FIG. 15 are the same as step S116A and step S119A to step S125A shown in FIG. 13 and would not be repeated.

In view of the above descriptions, the nitride semiconductor device and the manufacturing method of the nitride semiconductor device adjusts the 2DEG of the channel layer by forming the first polarization layer, the polarization control layer and the second polarization layer to achieve the normally-off operation of the GaN HEMT.

What is claimed is:

1. A nitride semiconductor device comprising:
a substrate;
a channel layer disposed on the substrate;
a first polarization layer disposed on the channel layer;
a polarization control layer disposed on the first polarization layer; and
a second polarization layer disposed on the polarization control layer;
wherein a lattice constant of the first polarization layer and a lattice constant of the second polarization layer are less than a lattice constant of the polarization control layer.

2. The nitride semiconductor device according to claim 1, wherein a material of the first polarization layer, a material of the polarization control layer and a material of the second polarization layer comprise AlGaN, and an Al composition ratio of the first polarization layer and an Al composition ratio of the second polarization layer are greater than an Al composition ratio of the polarization control layer.

3. The nitride semiconductor device according to claim 1, further comprising:
at least one buffer layer disposed between the substrate and the channel layer; and
a back barrier layer disposed on the at least one buffer layer.

4. The nitride semiconductor device according to claim 1, further comprising:
a first spacer layer disposed between the first polarization layer and the channel layer;
a second spacer layer disposed between the polarization control layer and the second polarization layer; and
a surface cap layer disposed on the second polarization layer.

5. The nitride semiconductor device according to claim 4, wherein the first spacer layer, the first polarization layer, the polarization control layer, the second spacer layer, the second polarization layer and the surface cap layer constitute a mesa structure exposing the channel layer, and the nitride semiconductor device further comprises:
a first passivation layer disposed on the mesa structure;
a drain electrode disposed on one side of the mesa structure, located on the first passivation layer, and extending from the first passivation layer to the channel layer; and
a source electrode disposed on the other side of the mesa structure, located on the first passivation layer, and extending from the first passivation layer to the channel layer.

6. The nitride semiconductor device according to claim 5, wherein the drain electrode comprises a first extension part and a first electrode part, the first extension part extends from the first passivation layer to the channel layer, and the first electrode part is disposed on the first passivation layer and passes through the first passivation layer to be connected to the first extension part; the source electrode comprises a second extension part and a second electrode part, the second extension part extends from the first passivation layer to the channel layer, and the second electrode part is disposed on the first passivation layer and passes through the first passivation layer to be connected to the second extension part; a material of the first extension part and a material of the second extension part comprise n type GaN, n type InGaN or metal materials.

7. The nitride semiconductor device according to claim 5, further comprising:
a second passivation layer disposed on the first passivation layer and having a through hole, wherein the through hole extends to the second spacer layer;
a gate insulator layer disposed on the second passivation layer, wherein one part of the gate insulator layer is disposed in the through hole; and
a gate electrode disposed in the through hole and electrically insulated from the second spacer layer by the gate insulator layer.

8. The nitride semiconductor device according to claim 7, further comprising an oxide layer disposed on a bottom of the through hole, wherein the gate insulator layer is disposed on the oxide layer.

9. The nitride semiconductor device according to claim 7, further comprising:
an ILD layer disposed on the gate electrode and located on the gate insulator layer; and
a plurality of first metal plugs disposed on the ILD layer and passing through the ILD layer, the gate insulator layer and the second passivation layer to be connected to the drain electrode and the source electrode.

10. The nitride semiconductor device according to claim 9, further comprising:
an IMD layer disposed on the ILD layer;
a plurality of second metal plugs disposed on the IMD layer and passing through the IMD layer to be connected to the plurality of first metal plugs; and
a third passivation layer disposed on the IMD layer and exposing the plurality of second metal plugs.

11. A nitride semiconductor device comprising:
a substrate;
a channel layer disposed on the substrate;
a spacer layer disposed on the channel layer; and
a polarization layer disposed on the spacer layer.

12. The nitride semiconductor device according to claim 11, further comprising:
at least one buffer layer disposed between the substrate and the channel layer; and
a back barrier layer disposed on the at least one buffer layer.

13. The nitride semiconductor device according to claim 11, wherein the spacer layer and the polarization layer constitute a mesa structure exposing the channel layer, and the nitride semiconductor device further comprises:
a first passivation layer disposed on the mesa structure;
a drain electrode disposed on one side of the mesa structure, located on the first passivation layer and extending from the first passivation layer to the channel layer; and
a source electrode disposed on the other side of the mesa structure, located on the first passivation layer, and extending from the first passivation layer to the channel layer.

14. The nitride semiconductor device according to claim 13, wherein the drain electrode comprises a first extension part and a first electrode part, the first extension part extends from the first passivation layer to the channel layer, and the first electrode part is disposed on the first passivation layer and passes through the first passivation layer to be connected to the first extension part; the source electrode comprises a second extension part and a second electrode part, the second extension part extends from the first passivation layer to the channel layer, and the second electrode part is disposed on the first passivation layer and passes through the first passivation layer to be connected to the second extension part; a material of the first extension part and a material of the second extension part comprise n type GaN, n type InGaN or metal materials.

15. The nitride semiconductor device according to claim 13, further comprising:
a second passivation layer disposed on the first passivation layer and having a through hole, wherein the through hole extends to the spacer layer;
a gate insulator layer disposed on the second passivation layer, wherein one part of the gate insulator layer is disposed in the through hole; and
a gate electrode disposed in the through hole and electrically insulated from the spacer layer by the gate insulator layer.

16. The nitride semiconductor device according to claim 15, further comprising an oxide layer disposed on a bottom of the through hole, wherein the gate insulator layer is disposed on the oxide layer.

17. The nitride semiconductor device according to claim 15, further comprising:
an ILD layer disposed on the gate electrode and located on the gate insulator layer; and
a plurality of first metal plugs disposed on the ILD layer and passing through the ILD layer, the gate insulator layer and the second passivation layer to be connected to the drain electrode and the source electrode.

18. The nitride semiconductor device according to claim 17, further comprising:
an IMD layer disposed on the ILD layer;
a plurality of second metal plugs disposed on the IMD layer and passing through the IMD layer to be connected to the plurality of first metal plugs; and
a third passivation layer disposed on the IMD layer and exposing the plurality of second metal plugs.

19. A manufacturing method of a nitride semiconductor device comprising:
sequentially forming a channel layer, a first spacer layer, a first polarization layer, a polarization control layer, a second spacer layer, a second polarization layer and a surface cap layer on a substrate;
partially etching the channel layer, the first spacer layer, the first polarization layer, the polarization control layer, the second spacer layer, the second polarization layer and the surface cap layer to form a mesa structure, wherein the mesa structure exposes the channel layer;
forming a first passivation layer on the mesa structure, and forming a drain electrode and a source electrode on two sides of the mesa structure, wherein the drain electrode and the source electrode are located on the first passivation layer and extends from the first passivation layer to the channel layer;
forming a second passivation layer on the first passivation layer, and partially etching the second passivation layer so that the etched second passivation layer has a through hole, wherein the through hole extends to the second spacer layer;
forming a gate insulator layer on the second passivation layer and in the through hole; and
forming a gate electrode on the gate insulator layer.

20. The manufacturing method of the nitride semiconductor device according to claim 19, before sequentially forming the channel layer, the first spacer layer, the first polarization layer, the polarization control layer, the second spacer layer, the second polarization layer and the surface cap layer on the substrate, the manufacturing method of the nitride semiconductor device further comprises: sequentially forming at least one buffer layer and a back barrier layer on the substrate.

21. The manufacturing method of the nitride semiconductor device according to claim 19, wherein forming the first passivation layer on the mesa structure, and forming the drain electrode and the source electrode on the two sides of the mesa structure comprise:
forming a first extension part and a second extension part on the two sides of the mesa structure;
forming the first passivation layer on the mesa structure, the first extension part and the second extension part;
partially etching the first passivation layer to expose the first extension part and the second extension part; and
separately forming a first electrode part and a second electrode part on the first extension part and the second extension part, wherein the first electrode part and the first extension part constitute the drain electrode, and the second electrode part and the second extension part constitute the source electrode.

22. The manufacturing method of the nitride semiconductor device according to claim 19, further comprising: forming an oxide layer on a bottom of the through hole, wherein the gate insulator layer is disposed on the oxide layer.

23. The manufacturing method of the nitride semiconductor device according to claim 19, further comprising:
forming an ILD layer on the gate electrode and the gate insulator layer;
partially etching the ILD layer to expose the drain electrode and the source electrode; and
forming a plurality of first metal plugs to be connected to the drain electrode and the source electrode.

24. The manufacturing method of the nitride semiconductor device according to claim 23, further comprising:
forming an IMD layer on the ILD layer and the plurality of first metal plugs;
partially etching the IMD layer to expose the plurality of first metal plugs;
forming a plurality of second metal plugs to be connected to the plurality of first metal plugs; and
forming a third passivation layer on the plurality of second metal plugs and the IMD layer and partially etching the third passivation layer to expose the plurality of second metal plugs.

25. A manufacturing method of a nitride semiconductor device comprising:
sequentially forming a channel layer, a spacer layer and a polarization layer on a substrate;
partially etching the channel layer, the spacer layer and the polarization layer to form a mesa structure, wherein the mesa structure exposes the channel layer;
forming a first passivation layer on the mesa structure, and forming a drain electrode and a source electrode on two sides of the mesa structure, wherein the drain electrode and the source electrode are located on the first passivation layer and extends from the first passivation layer to the channel layer;
forming a second passivation layer on the first passivation layer, and partially etching the second passivation layer so that the etched second passivation layer has a through hole, wherein the through hole extends to the spacer layer;
forming a gate insulator layer on the second passivation layer and in the through hole; and
forming a gate electrode on the gate insulator layer.

26. The manufacturing method of the nitride semiconductor device according to claim 25, before sequentially forming the channel layer, the spacer layer and the polarization layer on the substrate, the manufacturing method of the nitride semiconductor device further comprises:
sequentially forming at least one buffer layer and a back barrier layer on the substrate.

27. The manufacturing method of the nitride semiconductor device according to claim 25, wherein forming the first passivation layer on the mesa structure, and forming the drain electrode and the source electrode on the two sides of the mesa structure comprise:
forming a first extension part and a second extension part on the two sides of the mesa structure;
forming the first passivation layer on the mesa structure, the first extension part and the second extension part;
partially etching the first passivation layer to expose the first extension part and the second extension part; and
separately forming a first electrode part and a second electrode part on the first extension part and the second extension part, wherein the first electrode part and the first extension part constitute the drain electrode, and the second electrode part and the second extension part constitute the source electrode.

28. The manufacturing method of the nitride semiconductor device according to claim 25, further comprising: forming an oxide layer on a bottom of the through hole, wherein the gate insulator layer is disposed on the oxide layer.

29. The manufacturing method of the nitride semiconductor device according to claim 25, further comprising:
forming an ILD layer on the gate electrode and the gate insulator layer;
partially etching the ILD layer to expose the drain electrode and the source electrode; and
forming a plurality of first metal plugs to be connected to the drain electrode and the source electrode.

30. The manufacturing method of the nitride semiconductor device according to claim 29, further comprising:
forming an IMD layer on the ILD layer and the plurality of first metal plugs;
partially etching the IMD layer to expose the plurality of first metal plugs;
forming a plurality of second metal plugs to be connected to the plurality of first metal plugs; and
forming a third passivation layer on the plurality of second metal plugs and the IMD layer and partially etching the third passivation layer to expose the plurality of second metal plugs.
